(19) United States
(12) Patent Application Publication
(10) Pub. No.: US 2026/0136598 A1
(43) Pub. Date: May 14, 2026

(54) METAL BOUNDARIES

(71) Applicant: Taiwan Semiconductor Manufacturing Company, Ltd., Hsinchu (TW)

(72) Inventor: Tzu-Ging Lin, Kaohsiung City (TW)

(73) Assignee: Taiwan Semiconductor Manufacturing Company, Ltd., Hsinchu (TW)

(21) Appl. No.: 18/942,006

(22) Filed: Nov. 8, 2024

(51) Int. Cl. H01L 29/423; H01L 21/762; H01L 21/8234; H01L 21/8238; H01L 27/092; H01L 29/06; H01L 29/66; H01L 29/775; H01L 29/786

(52) U.S. Cl. CPC H10D 30/6735; H10D 30/014; H10D 30/43; H10D 30/6757; H10D 62/121; H10D 64/017; H10D 64/018; H10D 84/0128; H10D 84/013; H10D 84/0167; H10D 84/017; H10D 84/038; H10D 84/85; H10W 10/014; H10W 10/17

(57) ABSTRACT

Provided are semiconductor devices and methods for fabricating such devices. A method includes forming nanosheet channel layers over a semiconductor material; forming a protective liner on each of the nanosheet channel layers; forming fin structures from the nanosheet channel layers and from a portion of the semiconductor material; forming a sacrificial gate over the semiconductor material; performing a thermal anneal process while the protective liners are located on the nanosheet channel layers; removing a portion of a selected fin structure and an overlying portion of the sacrificial gate located over the portion of the selected fin structure to form a trench; forming an insulation structure in the trench; removing a remaining portion of the sacrificial gate to form a gate cavity partially defined by an end wall of the insulation structure; removing the protective liners from the nanosheet channel layers; and forming a metal gate in the cavity.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

Multi-gate devices have been introduced in an effort to improve gate control by increasing gate-channel coupling, to reduce OFF-state current, and to reduce short-channel effects (SCEs). One such multi-gate device that has been introduced is the fin field-effect transistor (FinFET). The FinFET gets its name from the fin-like structure which extends from a substrate on which it is formed, and which is used to form the FET channel. Another multi-gate device, introduced in part to address performance challenges associated with FinFETs, is the gate-all-around (GAA) transistor. GAA devices get their name from the gate structure which extends completely around the channel, providing better electrostatic control than FinFETs. FinFETs and GAA devices are compatible with conventional complementary metal-oxide-semiconductor (CMOS) processes and their three-dimensional structure allows them to be aggressively scaled while maintaining gate control and mitigating SCEs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a plan view of a layout of a multi-gate device, in accordance with some embodiments.

FIG. 2 is a flow chart illustrating a method, in accordance with some embodiments.

FIGS. 3A-3C to 9A-9C and FIG. 10 are cross-sectional views of a multi-gate device at various stages of fabrication, in accordance with some embodiments.

FIG. 11 is a plan view of a layout of a multi-gate device, in accordance with some embodiments.

FIG. 12 is a flow chart illustrating a method, in accordance with some embodiments.

FIGS. 13A-13B to 18A-18B and FIG. 19 are cross-sectional views of a multi-gate device at various stages of fabrication, in accordance with some embodiments.

FIG. 20 is a flow chart illustrating a method, in accordance with some embodiments.

FIGS. 21A-B to 33A-B are cross-sectional views of a multi-gate device at successive stages of fabrication, according to the method of FIG. 20.

FIG. 34 is a flow chart illustrating a method, in accordance with some embodiments.

FIGS. 35-41 are cross-sectional views of a multi-gate device at successive stages of fabrication, according to the method of FIG. 34.

FIGS. 42-45 are cross-sectional views of a multi-gate device at successive stages of fabrication of the method of FIGS. 20 and/or 34, in accordance with some embodiments.

FIGS. 46-49 are cross-sectional views of a multi-gate device at successive stages of fabrication of the method of FIGS. 20 and/or 34, in accordance with some embodiments.

FIGS. 50-52 are cross-sectional views of a multi-gate device at successive stages of fabrication according to the method of FIGS. 20 and/or 34.

FIGS. 53-55 are cross-sectional views of a multi-gate device at successive stages of fabrication according to the method of FIGS. 20 and/or 34.

FIGS. 56-58 are cross-sectional views of a multi-gate device at successive stages of fabrication according to the method of FIGS. 20 and/or 34.

FIG. 59 is a cross-sectional view of a multi-gate device formed according to the method of FIGS. 20 and/or 34.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “over”, “overlying”, “above”, “upper”, “top”, “under”, “underlying”, “beneath”, “below”, “lower”, “bottom”, “side”, and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In certain embodiments herein, a “material layer” is a layer that includes at least 50 wt. % of the identified material, for example at least 60 wt. % of the identified material, or at least 75 wt. % of the identified material, or at least 90 wt. % of the identified material; and a layer that is a “material” includes at least 50 wt. % of the identified material, for example at least 60 wt. % of the identified material, at least 75 wt. % of the identified material, or at least 90 wt. % of the identified material. For example, certain embodiments, each of a titanium nitride layer and a layer that is titanium nitride is a layer that is at least 50 wt. %, at least 60 wt. %, at least 75 wt. %, titanium nitride, or at least 90 wt. % titanium nitride.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

Presented herein are embodiments of semiconductor devices and of methods for fabricating such devices. Methods described herein may be easily integrated into the current process flow.

In advanced technology nodes, to increase the density of transistors, narrower STI feature widths and more nanosheet channels are desired. The channel length may be approaching the lithography limit (about 10 nm) in advanced nodes. The parasitic capacitance caused by high-K dielectrics may be dependent on the STI feature width and the number of nanosheets (i.e., the height of nanosheet stacks). In the scaling limit, as STI width reduces, pitch size shrinks, and height of nanosheet stack increases, leading to larger sidewall parasitic capacitance and lower STI parasitic capacitance. Herein, embodiments reduce the impact of high-K dielectrics on the sidewall to reduce the sidewall parasitic capacitance.

Embodiments herein are provided to reduce or minimize metal boundary effects at the interface between CPODE or CMODE insulation structures and metal gates.

For example, high-K dielectric liners formed on the end walls of insulation structures may cause metal boundary effects. Due to scaling, high-K dielectrics on insulation structure walls may substantially impact the threshold voltage of neighboring transistors.

Certain embodiments herein eliminate formation of high-K dielectric liners on the end walls of insulation structures.

Certain embodiments herein reduce metal boundary effects by increasing the distance between the high-K dielectrics on insulation structure sidewalls and adjacent transistors.

Certain embodiments herein provide for reduced metal boundary effects without performing cut-metal processing to etch the interface between an insulation feature and a metal gate. Such cut-metal processing may lead to damage to adjacent nanosheet channels.

Embodiments of the present disclosure offer advantages over the existing art, though it is understood that other embodiments may offer different advantages, not all advantages are necessarily discussed herein, and no particular advantage is required for all embodiments.

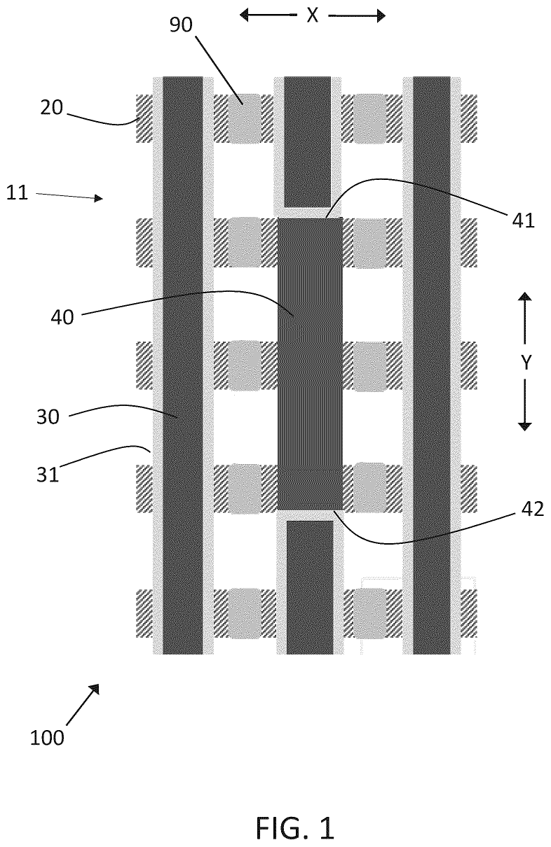

For purposes of the discussion that follows, FIG. 1 provides a simplified top-down layout view of a semiconductor device 100, such as a multi-gate device 100. Multi-gate devices 100 include those transistors whose gate structures are formed on at least two-sides of a channel region. These multi-gate devices may include a P-type metal-oxide-semiconductor device or an N-type metal-oxide-semiconductor multi-gate device.

In various embodiments, the multi-gate device 100 may include a FinFET device, gate-all-around (GAA) device, or other type of multi-gate device. A GAA device includes any device that has its gate structure, or portion thereof, formed on four-sides of a channel region (e.g., surrounding a portion of a channel region). Devices presented herein also include embodiments that have channel regions disposed in nanosheet channel(s), nanowire channel(s), bar-shaped channel(s), and/or other suitable channel configurations. Herein, “nanosheet channel” is intended to include nanowire channel and bar-shaped channel configurations. Presented herein are embodiments of devices 100 that may have one or more channel regions (e.g., nanosheets) associated with a single, contiguous gate structure. However, one of ordinary skill would recognize that the teaching can apply to a single channel (e.g., single nanosheet) or any number of channels. One of ordinary skill may recognize other examples of semiconductor devices that may benefit from aspects of the present disclosure.

The multi-gate device 100 is formed over a substrate 10. In some embodiments, the substrate 10 may be a semiconductor substrate such as a silicon substrate. The substrate 10 may include various layers, including conductive or insulating layers formed on a semiconductor substrate. The substrate 10 may include various doping configurations depending on design requirements as is known in the art. The substrate 10 may also include other semiconductors such as germanium, silicon carbide (SiC), silicon germanium (SiGe), or diamond. Alternatively, the substrate 10 may include a compound semiconductor and/or an alloy semiconductor. Further, the substrate 10 may optionally include an epi layer, may be strained for performance enhancement, may include a silicon-on-insulator (SOI) structure, and/or have other suitable enhancement features.

FIG. 1 is an overhead view of a unit cell 11, i.e., a portion of the semiconductor substrate 10. As shown, parallel active regions 20 are spaced apart from one another and extend in an X-direction. Source/drain features 90 are formed in the parallel active regions 20. Further, parallel gate lines 30 are spaced apart from one another and extend in a Y-direction perpendicular to the X-direction. Exemplary gate lines 30 are formed from conductive material such as metal and form gate structures for the multi-gate device 100. As shown, gate dielectric layers 31 surround the conductive gate lines 30.

As further shown in FIG. 1, a cut region or trench is formed in one gate line 30 and is filled with insulation to form an insulation structure 40 that may isolate adjacent devices from one another as described below. As used herein, “insulation”, “isolation”, and “dielectric” may be considered to be synonyms and are used in different instances only for purposes of clarity of description.

Methods described herein relate to the formation of the insulation structure 40, such as a Continuous Poly On Diffusion Edge (CPODE) structure 40, that divides a fin or fins in two. In certain embodiments, a portion of a selected fin structure is removed and replaced with insulation material.

For purposes of this disclosure, a “diffusion edge” may be equivalently referred to as an active edge, where for example an active edge abuts adjacent active regions. Further, an active region includes a region where transistor structures are formed (e.g., including source, drain, and gate/channel structures). In some examples, active regions may be disposed between insulating regions. The CPODE process may provide an isolation region between neighboring active regions, and thus neighboring transistors, by performing a dry etching process along an active edge (e.g., at a boundary of adjacent active regions) to form a cut region and filling the cut region with a dielectric, such as silicon nitride (SIN).

Before the CPODE process, the active edge may include a GAA dummy structure having a gate stack and a plurality of channels (e.g., nanosheet channels). The plurality of channels may each include a chemical oxide layer formed thereon, and high-K dielectric/metal gate layers may be formed over the chemical oxide layer and between adjacent channels of the plurality of channels. In addition, inner spacers may be disposed between adjacent channels at lateral ends of the plurality of channels. In various examples, source/drain epitaxial (epi) layers of adjacent active regions are disposed on either side of the GAA dummy structure (formed at the active edge), such that the adjacent source/drain epi layers are in contact with the inner spacers and plurality of channels of the GAA dummy structure.

In certain embodiments herein, a CPODE-first processing method, i.e., before metal gate formation, is utilized.

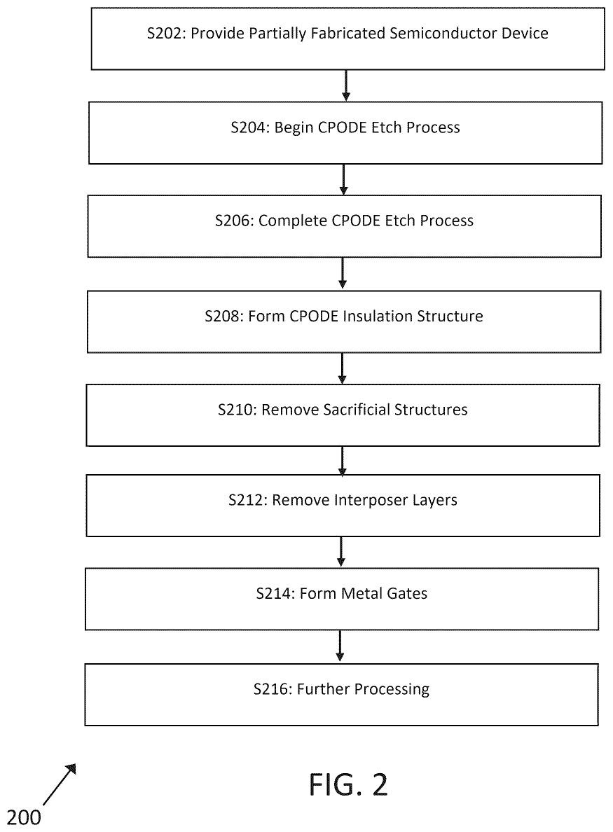

Referring to FIG. 2, illustrated therein is a method 200 of fabrication of a semiconductor device 100 (such as a multi-gate device) using a CPODE process, in accordance with various embodiments. Method 200 is discussed below with reference to a GAA device having a channel region that may be referred to as a nanosheet and which may include various geometries (e.g., cylindrical, bar-shaped) and dimensions. However, it will be understood that aspects of method 200, including the disclosed CPODE process, may be equally applied to other types of multi-gate devices without departing from the scope of the present disclosure. In some embodiments, method 200 may be used to fabricate the multi-gate device 100, described above with reference to FIG. 1. Thus, one or more aspects discussed above with reference to the multi-gate device 100 may also apply to method 200. It is understood that method 200 includes steps having features of a complementary metal-oxide-semiconductor (CMOS) technology process flow and thus, are only described briefly herein. Also, additional steps may be performed before, after, and/or during method 200.

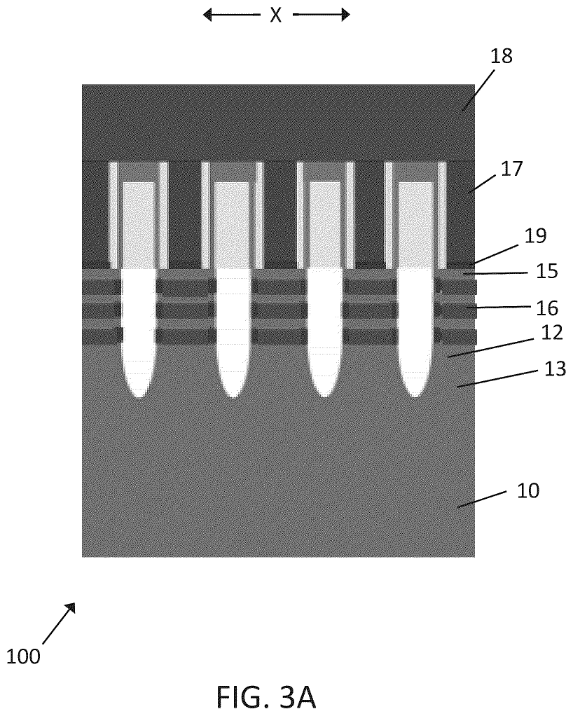

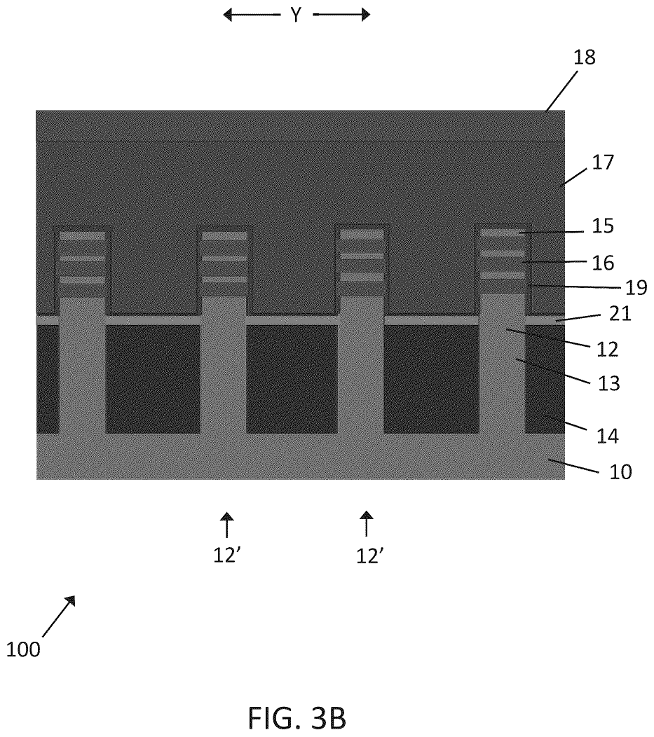

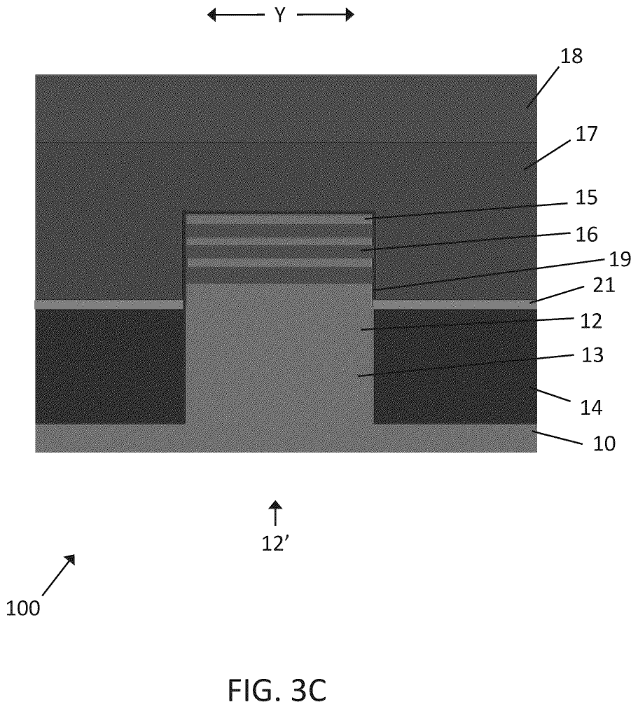

Method 200 is described below with reference to FIGS. 3-9C which illustrate the semiconductor device 100 at various stages of fabrication according to method 200. FIGS. 3A-9A provide cross-sectional views of an embodiment of the semiconductor device 100 along a plane substantially parallel to a plane defined by an X-axis through a fin 12 in FIG. 1.

FIGS. 3B-9B provide cross-sectional views of an embodiment of the semiconductor device 100 along a plane substantially parallel to a plane defined by an Y-axis through a gate line 30 in FIG. 1.

FIGS. 3C-9C provide cross-sectional views of an embodiment of the semiconductor device 100 along a plane substantially parallel to a plane defined by an Y-axis through a gate line 30 in FIG. 1.

FIGS. 3B-9B and 3C-9C differ in the number and dimension of fins that may be removed to form the insulation structure. The embodiments of FIGS. 3B-9B and 3C-9C may be present at different locations in a same unit cell 11, or may be considered to be alternative embodiments that are not both present.

The semiconductor device 100 may include various other devices and features, such as other types of devices such as additional transistors, bipolar junction transistors, resistors, capacitors, inductors, diodes, fuses, static random-access memory (SRAM) and/or other logic circuits, etc., but is simplified for a better understanding of the inventive concepts of the present disclosure. In some embodiments, the semiconductor device 100 includes a plurality of semiconductor devices (e.g., transistors), including PFETs, NFETs, etc., which may be interconnected. Moreover, it is noted that the process steps of method 200, including any descriptions given with reference to the figures are merely exemplary and are not intended to be limiting beyond what is specifically recited in the claims that follow.

Method 200 begins at block S202 where a partially fabricated multi-gate device 100 is provided. Referring to the example of FIGS. 3A-3C, in an embodiment of block S202, the method 200 forms structures 12, such as fins 12, over the substrate 10. The fins 12 extend in the X-direction and are distanced apart from one another in the Y-direction perpendicular to the X-direction. In some embodiments, the substrate 10 may be a semiconductor substrate such as a silicon substrate. The substrate 10 may include various layers, including conductive or insulating layers formed on a semiconductor substrate. The substrate 10 may include various doping configurations depending on design requirements as is known in the art. The substrate 10 may also include other semiconductors such as germanium, silicon carbide (SiC), silicon germanium (SiGe), or diamond. Alternatively, the substrate 10 may include a compound semiconductor and/or an alloy semiconductor. Further, the substrate 10 may optionally include an epi layer, may be strained for performance enhancement, may include a silicon-on-insulator (SOI) structure, and/or have other suitable enhancement features.

The fins 12 may include nanosheet channel layers, collectively identified by reference number 15, interleaved with interposer layers, collectively identified by reference number 16. In some embodiments, the nanosheet channel layers 15 may include silicon (Si) and interposer layers 16 may include silicon germanium (SiGe). However, in some embodiments, the nanosheet channel layers 15 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. In such embodiments, the interposer layers 16 may include silicon (Si) or another material different from the material of the nanosheet channel layers 15. By way of example, the nanosheet channel layers 15 may be epitaxially grown by a molecular beam epitaxy (MBE) process, a metalorganic chemical vapor deposition (MOCVD) process, and/or other suitable epitaxial growth processes.

As shown, a liner 19 may be formed along sidewalls and over the top of the stack of layers 15 and 16. An exemplary liner 19 is silicon oxide.

In various embodiments, each of the fins 12 includes a substrate portion 13 formed from the substrate 10. It is noted that while the fins 12 are illustrated as including three (3) nanosheet channel layers 15, this is for illustrative purposes only and is not intended to be limiting beyond what is specifically recited in the claims. It can be appreciated that any number of nanosheet channel layers 15 can be formed, where for example, the number of nanosheet channel layers 15 depends on the desired number of channels regions for the GAA device (e.g., the device 100). In some embodiments, the number of nanosheet channel layers 15 is between three and ten.

Shallow trench isolation (STI) features 14 may also be formed interposing the fins 12. In some embodiments, the STI features 14 include SiO₂, silicon nitride, silicon oxynitride, fluorine-doped silicate glass (FSG), a low-k dielectric, combinations thereof, and/or other suitable materials known in the art. In various examples, the dielectric layer used to form the STI features may be deposited by a CVD process, a subatmospheric CVD (SACVD) process, a flowable CVD process, an ALD process, a PVD process, and/or other suitable process.

As shown, a hard mask 21 is formed over the STI features 14. The STI hard mask 21 may be silicon nitride or other suitable material.

As further shown in FIGS. 3A-3C, the partially fabricated multi-gate device 100 further includes a sacrificial layer 17, such as a sacrificial or dummy gate structure 17 extending in the Y-direction. Sacrificial gate structures 17 are spaced from one another in the X-direction and are formed over portions of the fins 12 which are to be channel regions. The sacrificial gate structures 17 may extend over a number of adjacent fins 12 as shown. The sacrificial gate structures 17 lie directly over and define the channel regions of the GAA devices to be formed. Each of the sacrificial gate structures 17 may include a sacrificial gate dielectric and a sacrificial gate electrode over the sacrificial gate dielectric.

The sacrificial gate structures 17 are formed by first blanket depositing a sacrificial gate dielectric layer over the fins 12. A sacrificial gate electrode layer is then blanket deposited on the sacrificial gate dielectric layer and over the fins 12. The sacrificial gate dielectric layer includes silicon oxide, silicon nitride, or a combination thereof. The thickness of the sacrificial gate electrode layer is in a range from about 100 nm to about 200 nm in some embodiments. The sacrificial gate electrode layer includes silicon such as polycrystalline silicon or amorphous silicon. The thickness of the sacrificial gate dielectric layer is in a range from about 1 nm to about 5 nm in some embodiments. In some embodiments, the sacrificial gate structure 17 is subjected to a planarization operation. The sacrificial gate dielectric layer and the sacrificial gate electrode layer are deposited using CVD, including LPCVD and PECVD, PVD, ALD, or other suitable process. The sacrificial gate dielectric layer and the sacrificial gate electrode layer may be masked and patterned to form the sacrificial gate structures 17.

As shown, a mask layer 18 is formed over the sacrificial gate structures 17. The mask layer 18 may include a mask layer such as silicon oxide and a mask layer such as silicon nitride.

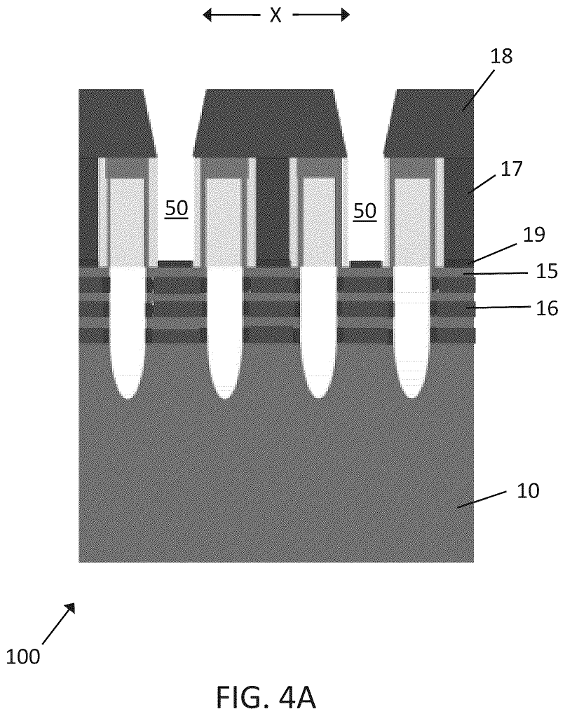

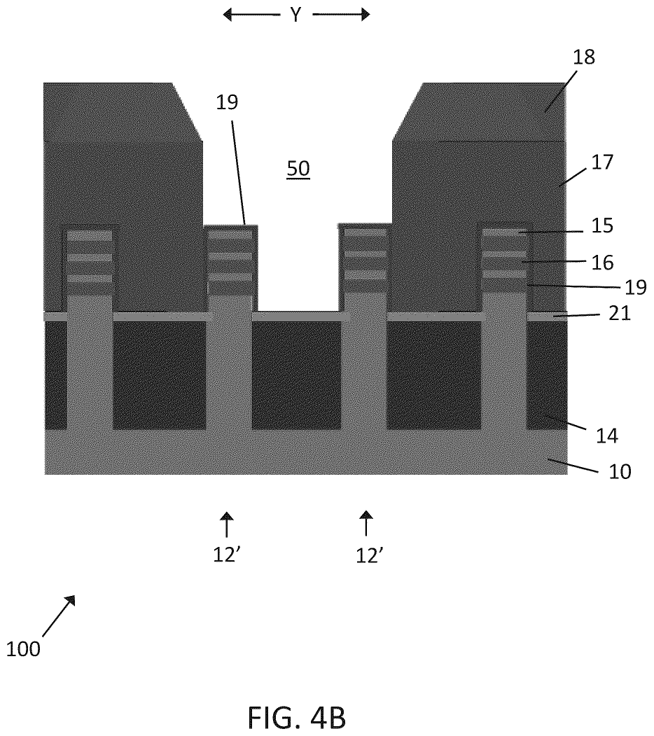

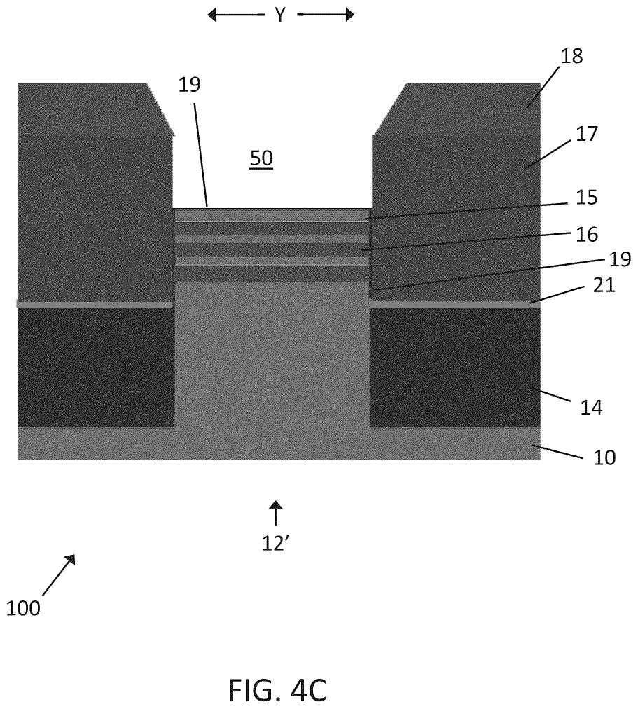

Cross-referencing FIGS. 2 and 4A-4C, method 200 may continue at block S204 with beginning the CPODE etch process. Specifically, the mask layer is patterned before an etch is performed to remove a portion of the sacrificial gate structure 17 over lying selected fins 12′ for removal. As a result, a trench 50 is formed.

The etch process at block S204 may land on the liner 19 and the STI hard mask 21 such that the liner 19 remains over and surrounding the stack of layers 15 and 16 and the STI hard mask 21 remains covering the STI features 14.

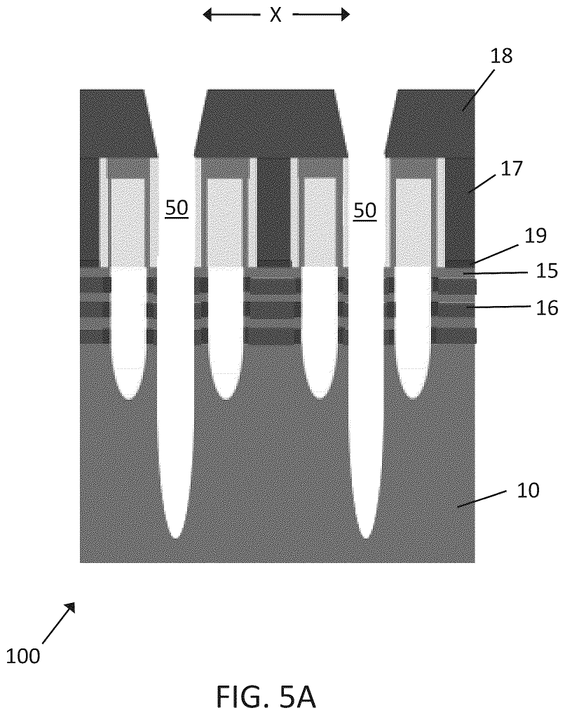

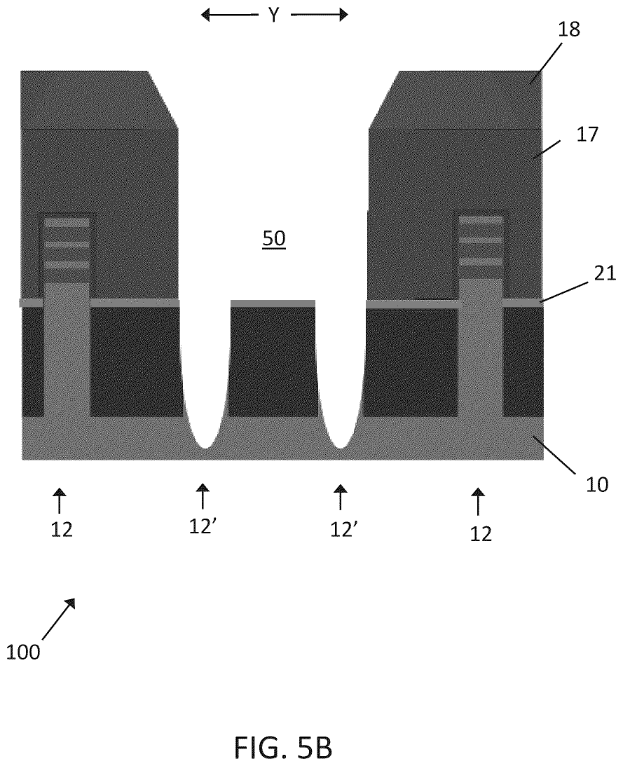

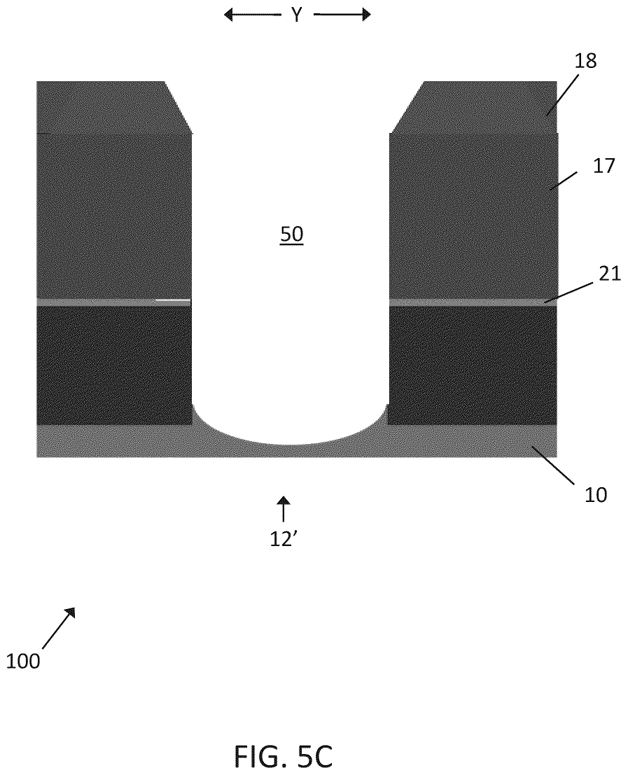

Cross-referencing FIGS. 2 and 5A-5C, method 200 may continue at block S206 with completing the CPODE etch process. Specifically, at block S206, the uncovered liner 19 and underlying stack of layers 15 and 16 forming the portions of the selected fins 12′ are removed. As a result, trench 50 extends into the substrate 10.

The etch process at block S206 may land on the STI hard mask 21 such that the STI hard mask 21 remains covering the STI features 14.

As illustrated, method 200 includes removing a portion of at least one structure 12′ to form a trench 50. The trench 50 extends across the fins 12, i.e., in the Y-direction.

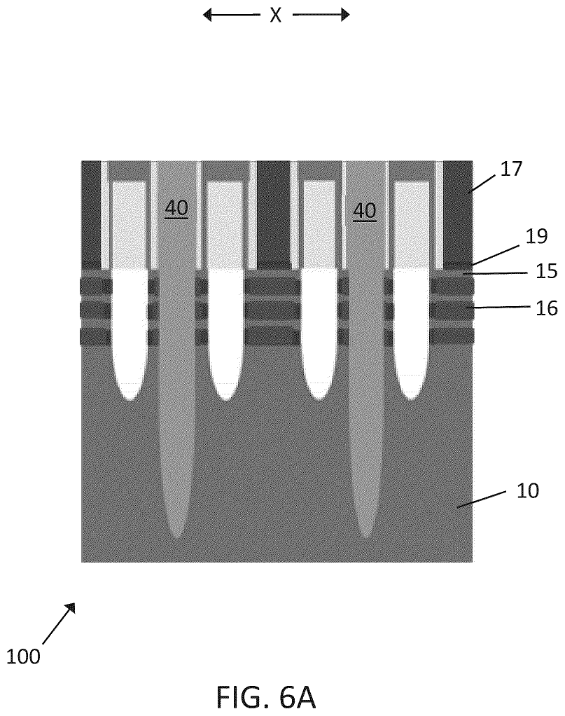

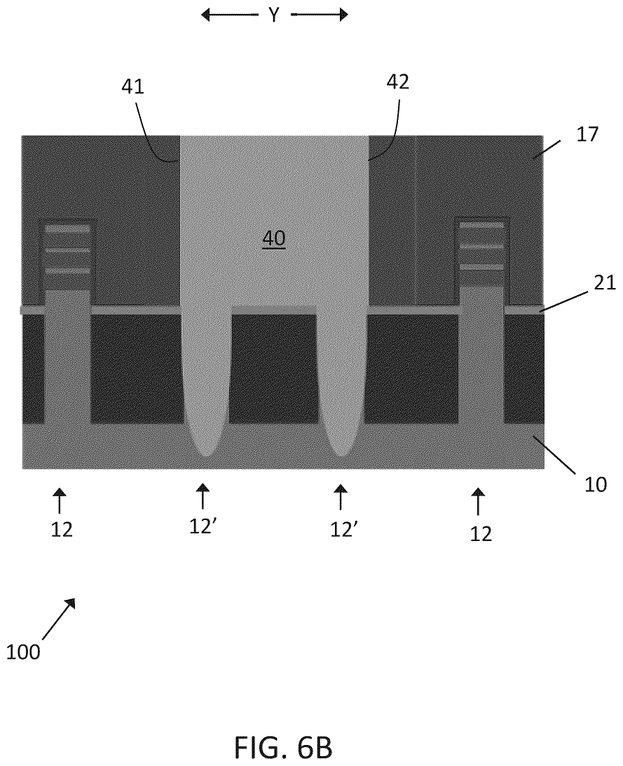

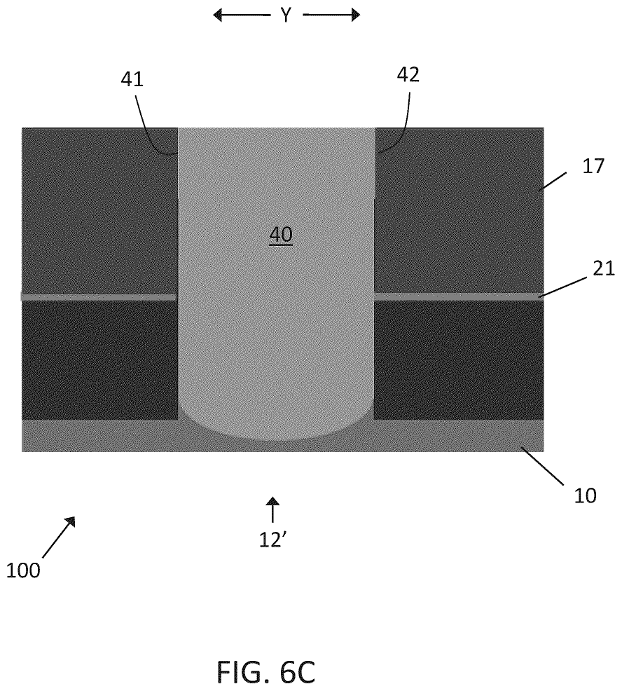

Cross-referencing FIGS. 2 and 6A-6C, method 200 may continue at block S208 with forming the CPODE insulation structure 40 in the trench. The CPODE insulation structure 40 may be formed by a fill material deposited in the trench 50. For example, the fill material may be silicon oxide. An overburden portion of the fill material may be removed by a planarization process.

The CPODE insulation structure 40 extends in the Y-direction from a first end wall 41 to a second end wall 42. Thus, each end wall 41 and 42 extends in the X-direction.

Thus, method 200 forms an insulation structure 40 in the trench 50, and the insulation structure 40 terminates at a first end wall 41, terminates at a second end wall 42, and extends in the Y-direction from the first end wall 41 to the second end wall 42.

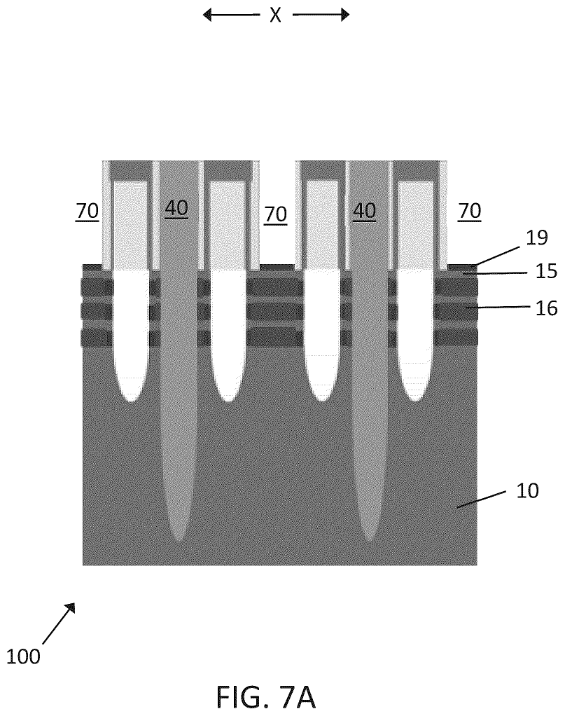

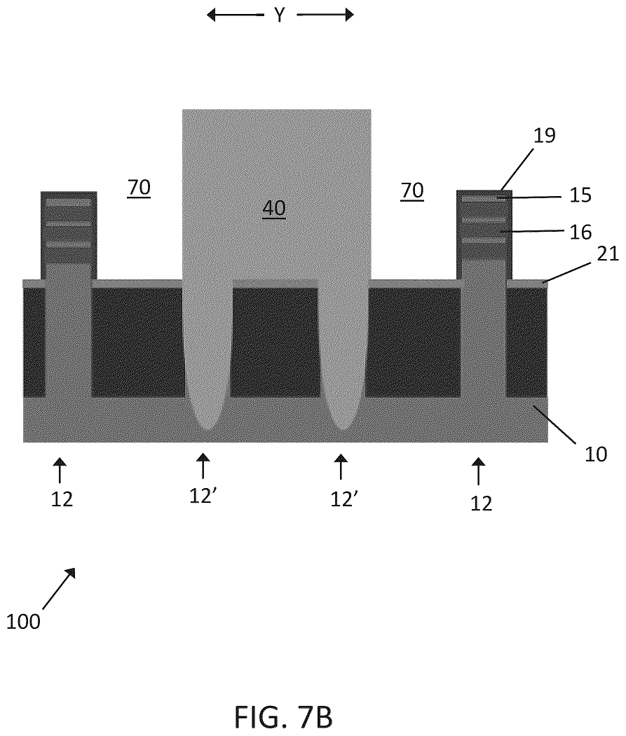

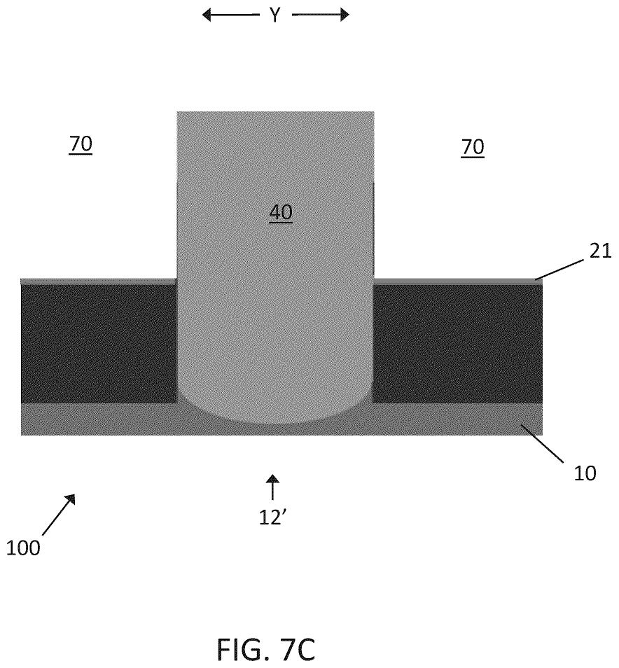

Cross-referencing FIGS. 2 and 7A-7C, method 200 may continue at block S210 with removing the sacrificial gate structures 17 to form gate cavities 70. As shown, the gate cavities 70 are partially defined by, i.e., bounded by, the end walls 41 and 42 of the CPODE insulation structure 40. The etch performed to remove the sacrificial gate structures 17 at block

S210 lands on the liner 19 and the STI hard mask 21 such that the liner 19 remains over and surrounding the stack of layers 15 and 16 and the STI hard mask 21 remains covering the STI features 14.

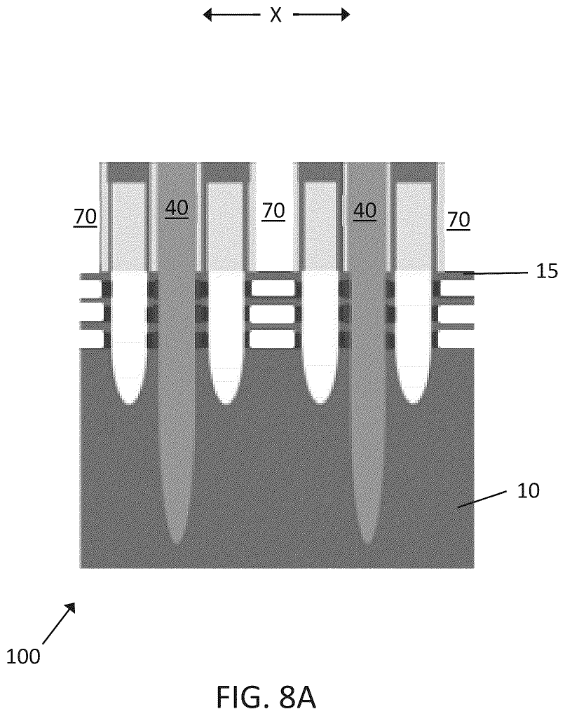

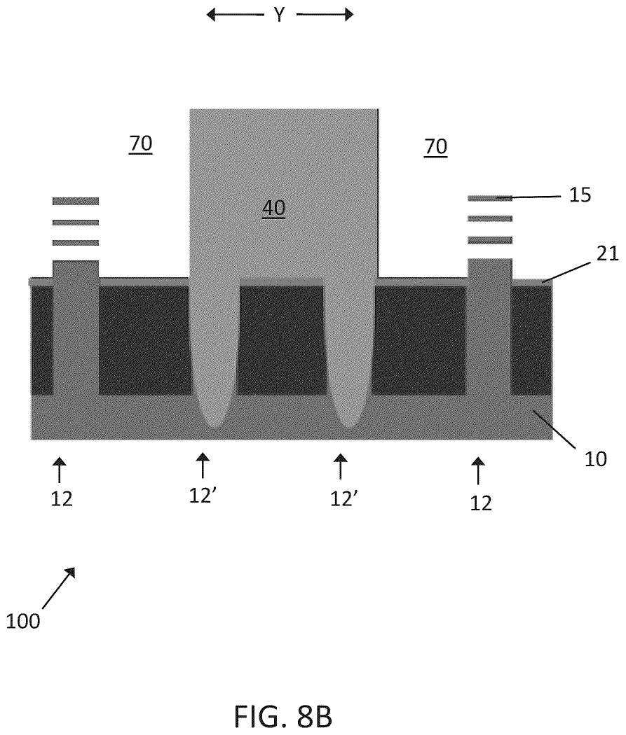

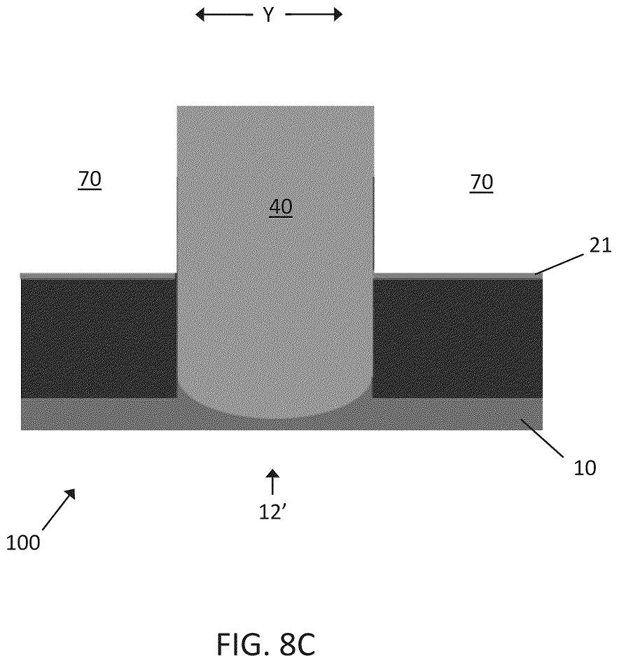

Cross-referencing FIGS. 2 and 8A-8C, method 200 may continue at block S212 with removing the interposer layers 16, leaving the nanosheet channel layers 15 spaced above the fins 12 to define the nanosheet channel regions. As shown, the etch performed at block S212 removes liner 19 before removing interposer layers 16. The etch performed at block S212 lands on the STI hard mask 21 such that the STI hard mask 21 remains covering the STI features 14.

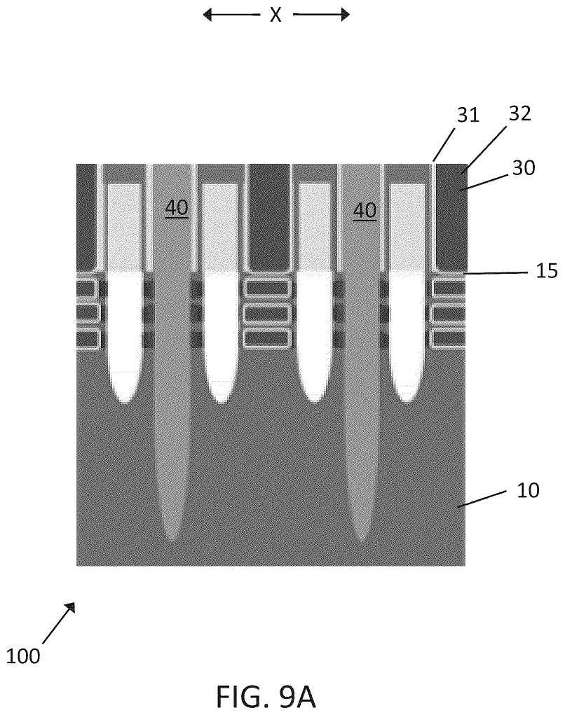

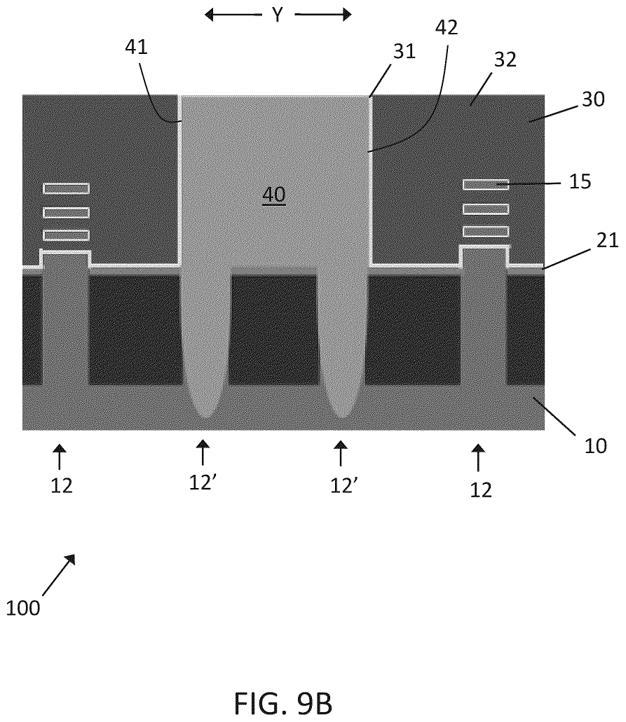

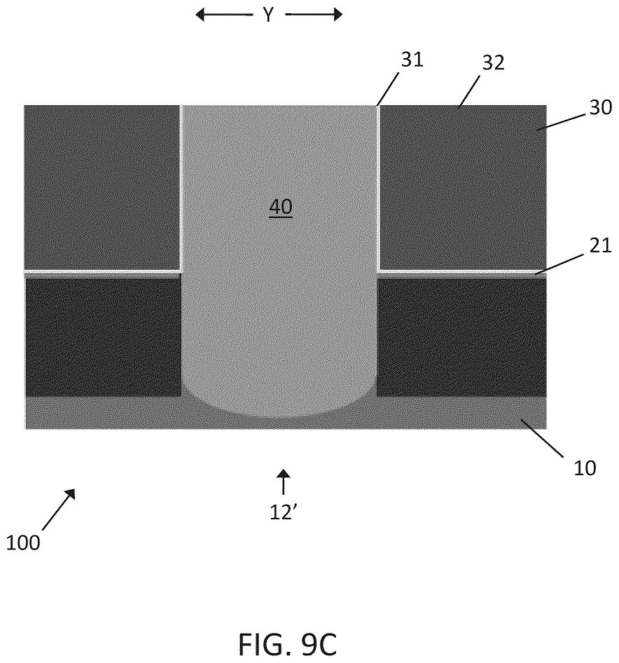

Cross-referencing FIGS. 2 and 9A-9C, method 200 may continue at block S214 with forming metal gates 30 in the gate cavities 70. Specifically, method 200 may include lining the gate cavities 70 with a dielectric liner 31. For example, a high-K gate dielectric layer 31 may be deposited along the end walls 41 and 42 that extend in the X-direction, along cavity sidewalls extending in the Y-direction, on the STI hard mask 21 at the cavity bottom, and around the nanosheet channel layers 15.

High-K gate dielectrics, as used and described herein, include dielectric materials having a high dielectric constant, for example, greater than that of thermal silicon oxide (about 3.9). An exemplary high-K gate dielectric layer 31 may include a high-K dielectric material such as hafnium oxide (HfO₂). Alternatively, the high-K gate dielectric layer 31 may include other high-K dielectric materials, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr) TiO₃ (BST), Al₂O₃, Si₃N₄, oxynitrides (SiON), combinations thereof, or other suitable material. The high-K gate dielectric layer 31 may be formed by ALD, physical vapor deposition (PVD), CVD, oxidation, and/or other suitable methods

Formation of the metal gates 30 further includes filling the gate cavities 70 with fill material 32. The fill material 32 may include multiple layers of a metal, metal alloy, or metal silicide. The fill material 32 may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the fill material 32 may include Ti, Ag, Al, TiAlN, TaC, TaCN, TaSiN, Mn, Zr, TiN, TaN, Ru, Mo, Al, WN, Cu, W, Re, Ir, Co, Ni, other suitable metal materials or a combination thereof. In various embodiments, the fill material 32 may be formed by ALD, PVD, CVD, e-beam evaporation, or other suitable process. Further, the fill material 32 may be formed separately for N-type and P-type transistors which may use different metal layers. In addition, the fill material 82 may provide an N-type or P-type work function, may serve as a transistor gate electrode, and in at least some embodiments, the fill material 32 may include a polysilicon layer. In some examples, the fill material 32 may include selectively-grown tungsten (W) and/or a fluorine-free tungsten (FFW) layer.

As shown in FIGS. 9A-9C, a chemical mechanical planarization (CMP) process may be performed to remove overburden portions of the liner 31 and fill material 32 to define the metal gates 30 in the gate cavities 70.

As shown in FIG. 2, method 200 may continue at block S216 with further processing, such as performing middle end of line (MEOL) processing and back end of line (BEOL) processing.

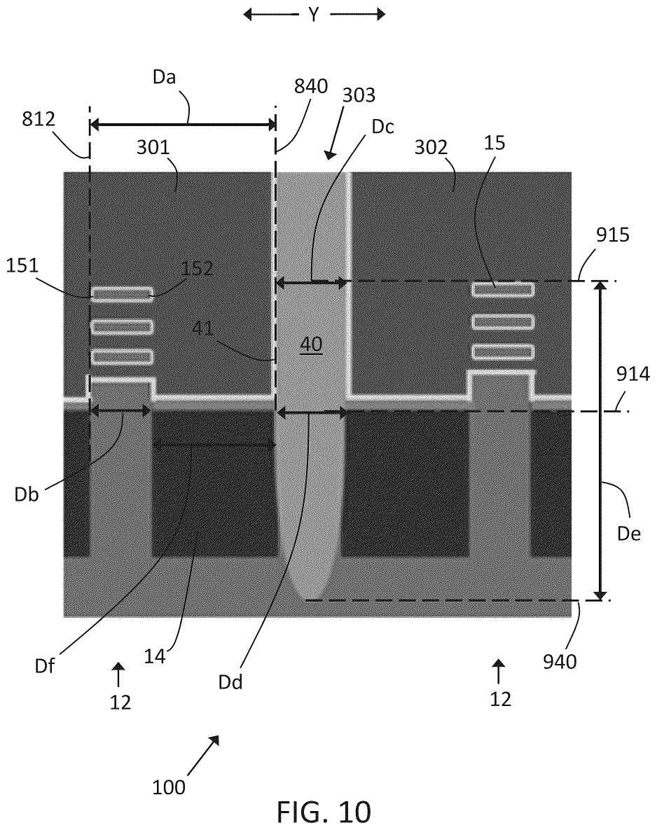

FIG. 10 is a Y-cut cross-sectional view, similar to FIGS. 9B and 9C, illustrating an embodiment of an insulation structure 40 formed between two fins 12.

As shown in FIG. 10, fin 12 has two opposite sidewalls 151 and 152. Sidewall 151 of fin 12 defines a vertical plane 912, and the end wall 41 of the insulation structure 40 defines a vertical plane 840. As further shown, the upper surface of top nanosheet layer 15 defines an upper nanosheet plane 915, the upper surface of STI feature 14 defines an upper STI plane 914, and the bottom trough point of insulation structure 40 defines a bottom-most plane 940.

As shown in FIG. 10, insulation structure 40 is formed with a pitch or horizontal distance Da from plane 812 to plane 840. In certain embodiments, the pitch Da is from 63.2 to 63.9 nanometers (nm), for example 63.6 nm.

As shown in FIG. 10, fin 12 is formed with a critical dimension or horizontal width Db at plane 914. In certain embodiments, the critical dimension Db is from 24.4 to 25.5 nm, for example 24.9 nm.

As shown in FIG. 10, insulation feature 60 is formed with a critical dimension or horizontal width Dc at plane 915. In certain embodiments, the critical dimension Dc is from 36.3 to 39.3 nm, for example 38.0 nm.

As shown in FIG. 10, insulation feature 60 is formed with a critical dimension or horizontal width Dd at plane 914. In certain embodiments, the critical dimension Dd is from 27.1 to 35.2 nm, for example 30.9 nm.

As shown in FIG. 10, insulation feature 60 is formed with a vertical depth De from plane 915 to plane 940. In certain embodiments, the vertical depth De is from 187.9 to 192.4 nm, for example 195.7 nm.

As shown in FIG. 10, side wall 152 of insulation feature 60 is distanced from the end wall 41 of the insulation structure 40 by a lateral distance Df. In certain embodiments, the lateral distance Df is at least 20 nm, such as at least 25 nm, at least 30 nm, at least 32 nm, at least 34 nm, at least 36 nm, at least 37 nm, at least 38 nm, at least 39 nm, at least 40 nm, at least 41 nm, at least 42 nm, at least 43 nm, at least 44 nm, or at least 45 nm. In certain embodiments, the lateral distance Df is at most 22 nm, such as at most 25 nm, at most 30 nm, at most 32 nm, at most 34 nm, at most 36 nm, at most 37 nm, at most 38 nm, at most 39 nm, at most 40 nm, at most 41 nm, at most 42 nm, at most 43 nm, at most 44 nm, at most 45 nm, or at most 46 nm.

In certain embodiments, the critical dimension Dc is from 50% to 80% of the pitch Da. For example, critical dimension Dc may be at least 50%, at least 51%, at least 52%, at least 53%, at least 54%, at least 55%, at least 56%, at least 57%, at least 58%, at least 59%, at least 60%, at least 61%, or at least 62% of the pitch Da. Further, critical dimension Dc may be at most 51%, at most 52%, at most 53%, at most 54%, at most 55%, at most 56%, at most 57%, at most 58%, at most 59%, at most 60%, at most 61%, at most 62%, at most 63%, at most 64%, or at most 65% of the pitch Da.

In certain embodiments, the critical dimension Dd is from 30% to 70% of the pitch Da. For example, critical dimension Dd may be at least 30%, at least 35%, at least 40%, at least 41%, at least 42%, at least 43%, at least 44%, at least 45%, at least 46%, at least 47%, at least 48%, at least 49%, at least 50%, at least 51%, at least 52%, at least 53%, at least 54%, or at least 55% of the pitch Da. Further, critical dimension Dd may be at most 40%, at most 41%, at most 42%, at most 43%, at most 44%, at most 45%, at most 46%, at most 47%, at most 48%, at most 49%, at most 50%, at most 51%, at most 52%, at most 53%, at most 54%, at most 55%, or at most 56% of the pitch Da.

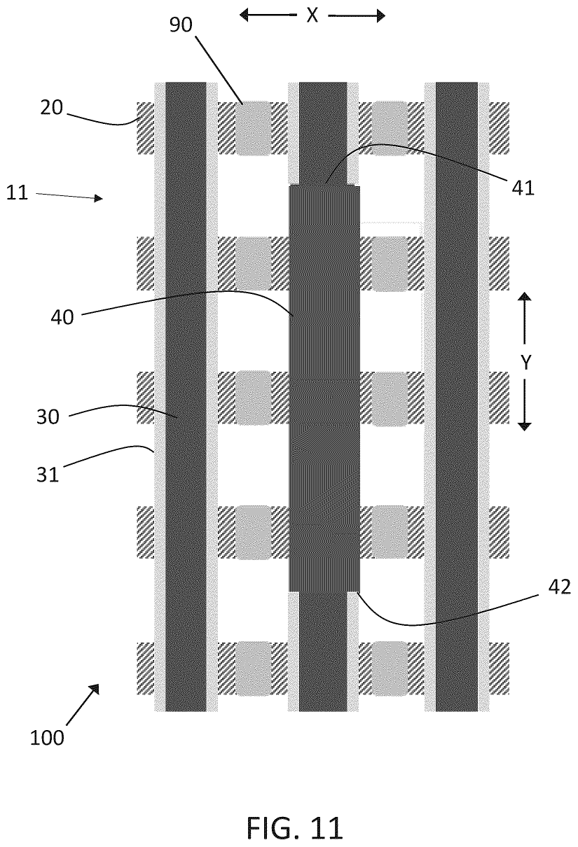

FIGS. 1-10 describe embodiments in which a CPODE process is performed to form the insulation structure 40 before the metal gate 30 is formed. In other embodiments, the metal gate 30 may be formed before a CMODE process is performed to form the insulation structure 40. FIGS. 11-19 describe such an embodiments.

FIG. 11 provides a simplified top-down layout view of a semiconductor device 100, such as a multi-gate device 100. Multi-gate devices 100 include those transistors whose gate structures are formed on at least two-sides of a channel region. These multi-gate devices may include a P-type metal-oxide-semiconductor device or an N-type metal-oxide-semiconductor multi-gate device.

In various embodiments, the multi-gate device 100 may include a FinFET device, gate-all-around (GAA) device, or other type of multi-gate device. A GAA device includes any device that has its gate structure, or portion thereof, formed on four-sides of a channel region (e.g., surrounding a portion of a channel region). Devices presented herein also include embodiments that have channel regions disposed in nanosheet channel(s), nanowire channel(s), bar-shaped channel(s), and/or other suitable channel configurations. Herein, “nanosheet channel” is intended to include nanowire channel and bar-shaped channel configurations. Presented herein are embodiments of devices 100 that may have one or more channel regions (e.g., nanosheets) associated with a single, contiguous gate structure. However, one of ordinary skill would recognize that the teaching can apply to a single channel (e.g., single nanosheet) or any number of channels. One of ordinary skill may recognize other examples of semiconductor devices that may benefit from aspects of the present disclosure.

The multi-gate device 100 is formed over a substrate 10. In some embodiments, the substrate 10 may be a semiconductor substrate such as a silicon substrate. The substrate 10 may include various layers, including conductive or insulating layers formed on a semiconductor substrate. The substrate 10 may include various doping configurations depending on design requirements as is known in the art. The substrate 10 may also include other semiconductors such as germanium, silicon carbide (SiC), silicon germanium (SiGe), or diamond. Alternatively, the substrate 10 may include a compound semiconductor and/or an alloy semiconductor. Further, the substrate 10 may optionally include an epi layer, may be strained for performance enhancement, may include a silicon-on-insulator (SOI) structure, and/or have other suitable enhancement features.

FIG. 11 is an overhead view of a unit cell 11, i.e., a portion of the semiconductor substrate 10. As shown, parallel active regions 20 are spaced apart from one another and extend in an X-direction. Source/drain features 90 are formed in the parallel active regions 20. Further, parallel gate lines 30 are spaced apart from one another and extend in a Y-direction perpendicular to the X-direction. Exemplary gate lines 30 are formed from conductive material such as metal and form gate structures for the multi-gate device 100. As shown, gate dielectric layers 31 surround the conductive gate lines 30.

As further shown in FIG. 11, a cut region or trench is formed in one gate line 30 and is filled with insulation to form an insulation structure 40 that may isolate adjacent devices from one another as described below. As used herein, “insulation”, “isolation”, and “dielectric” may be considered to be synonyms and are used in different instances only for purposes of clarity of description.

Methods described herein relate to the formation of the insulation structure 40, such as a Continuous Metal On Diffusion Edge (CMODE) structure 40, that divides a fin or fins in two. In certain embodiments, a portion of a selected fin structure is removed and replaced with insulation material.

For purposes of this disclosure, a “diffusion edge” may be equivalently referred to as an active edge, where for example an active edge abuts adjacent active regions. Further, an active region includes a region where transistor structures are formed (e.g., including source, drain, and gate/channel structures). In some examples, active regions may be disposed between insulating regions. The CMODE process may provide an isolation region between neighboring active regions, and thus neighboring transistors, by performing a dry etching process along an active edge (e.g., at a boundary of adjacent active regions) to form a cut region and filling the cut region with a dielectric, such as silicon nitride (SIN).

Before the CMODE process, the active edge may include a metal gate structure having a gate stack and a plurality of channels (e.g., nanosheet channels). The plurality of channels may each include a chemical oxide layer formed thereon, and high-K dielectric/metal gate layers may be formed over the chemical oxide layer and between adjacent channels of the plurality of channels. In addition, inner spacers may be disposed between adjacent channels at lateral ends of the plurality of channels. In various examples, source/drain epitaxial (epi) layers of adjacent active regions are disposed on either side of the GAA dummy structure (formed at the active edge), such that the adjacent source/drain epi layers are in contact with the inner spacers and plurality of channels of the GAA dummy structure.

In certain embodiments herein, a CMODE-last processing method, i.e., after metal gate formation, is utilized.

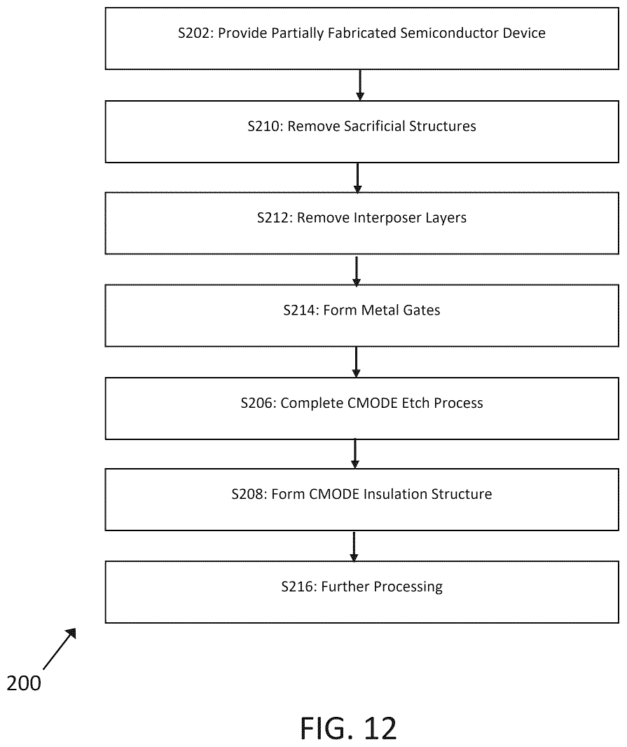

Referring to FIG. 12, illustrated therein is a method 200 of fabrication of a semiconductor device 100 (such as a multi-gate device) using a CPODE process, in accordance with various embodiments. Method 200 is discussed below with reference to a GAA device having a channel region that may be referred to as a nanosheet and which may include various geometries (e.g., cylindrical, bar-shaped) and dimensions. However, it will be understood that aspects of method 200, including the disclosed CPODE process, may be equally applied to other types of multi-gate devices without departing from the scope of the present disclosure. In some embodiments, method 200 may be used to fabricate the multi-gate device 100, described above with reference to FIG. 11. Thus, one or more aspects discussed above with reference to the multi-gate device 100 may also apply to method 200. It is understood that method 200 includes steps having features of a complementary metal-oxide-semiconductor (CMOS) technology process flow and thus, are only described briefly herein. Also, additional steps may be performed before, after, and/or during method 200.

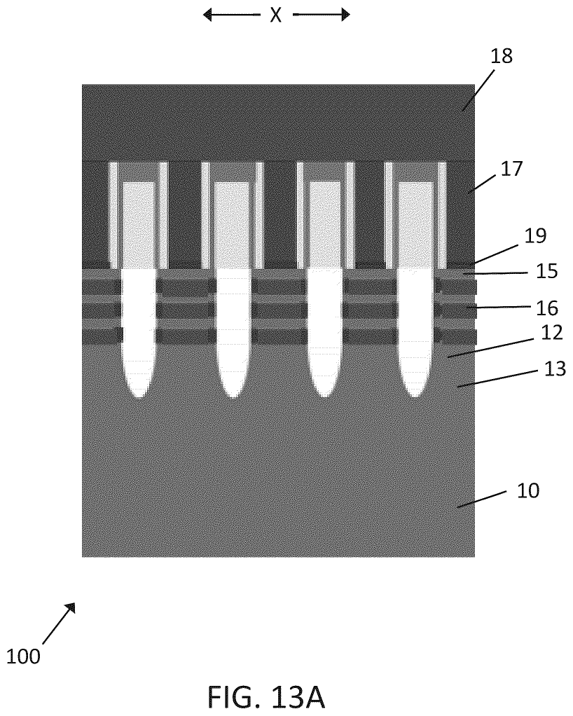

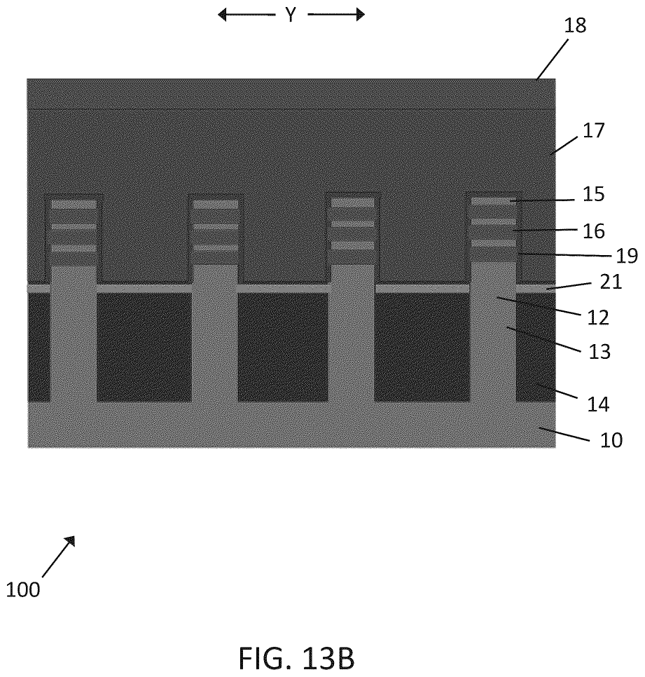

Method 200 is described below with reference to FIGS. 13-18 which illustrate the semiconductor device 100 at various stages of fabrication according to method 200. FIGS. 13A-18A provide cross-sectional views of an embodiment of the semiconductor device 100 along a plane substantially parallel to a plane defined by an X-axis through a fin 12 in FIG. 1.

FIGS. 13B-18B provide cross-sectional views of an embodiment of the semiconductor device 100 along a plane substantially parallel to a plane defined by an Y-axis through a gate line 30 in FIG. 1.

The semiconductor device 100 may include various other devices and features, such as other types of devices such as additional transistors, bipolar junction transistors, resistors, capacitors, inductors, diodes, fuses, static random-access memory (SRAM) and/or other logic circuits, etc., but is simplified for a better understanding of the inventive concepts of the present disclosure. In some embodiments, the semiconductor device 100 includes a plurality of semiconductor devices (e.g., transistors), including PFETs, NFETs, etc., which may be interconnected. Moreover, it is noted that the process steps of method 200, including any descriptions given with reference to the figures are merely exemplary and are not intended to be limiting beyond what is specifically recited in the claims that follow.

Method 200 begins at block S202 where a partially fabricated multi-gate device 100 is provided. Referring to the example of FIGS. 13A-13B, in an embodiment of block S202, the method 200 forms structures 12, such as fins 12, over the substrate 10. The fins 12 extend in the X-direction and are distanced apart from one another in the Y-direction perpendicular to the X-direction. In some embodiments, the substrate 10 may be a semiconductor substrate such as a silicon substrate. The substrate 10 may include various layers, including conductive or insulating layers formed on a semiconductor substrate. The substrate 10 may include various doping configurations depending on design requirements as is known in the art. The substrate 10 may also include other semiconductors such as germanium, silicon carbide (SiC), silicon germanium (SiGe), or diamond. Alternatively, the substrate 10 may include a compound semiconductor and/or an alloy semiconductor. Further, the substrate 10 may optionally include an epi layer, may be strained for performance enhancement, may include a silicon-on-insulator (SOI) structure, and/or have other suitable enhancement features.

The fins 12 may include nanosheet channel layers, collectively identified by reference number 15 interleaved with interposer layers, collectively identified by reference number 16. In some embodiments, the nanosheet channel layers 15 may include silicon (Si) and interposer layers 16 may include silicon germanium (SiGe). However, in some embodiments, the nanosheet channel layers 15 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. By way of example, the nanosheet channel layers 15 may be epitaxially grown by a molecular beam epitaxy (MBE) process, a metalorganic chemical vapor deposition (MOCVD) process, and/or other suitable epitaxial growth processes.

As shown, a liner 19 may be formed along sidewalls and over the top of the stack of layers 15 and 16. An exemplary liner 19 is silicon oxide.

In various embodiments, each of the fins 12 includes a substrate portion 13 formed from the substrate 10. It is noted that while the fins 12 are illustrated as including three (3) nanosheet channel layers 15, this is for illustrative purposes only and is not intended to be limiting beyond what is specifically recited in the claims. It can be appreciated that any number of nanosheet channel layers 15 can be formed, where for example, the number of nanosheet channel layers 15 depends on the desired number of channels regions for the GAA device (e.g., the device 100). In some embodiments, the number of nanosheet channel layers 15 is between three and ten.

Shallow trench isolation (STI) features 14 may also be formed interposing the fins 12. In some embodiments, the STI features 14 include SiO₂, silicon nitride, silicon oxynitride, fluorine-doped silicate glass (FSG), a low-k dielectric, combinations thereof, and/or other suitable materials known in the art. In various examples, the dielectric layer used to form the STI features may be deposited by a CVD process, a subatmospheric CVD (SACVD) process, a flowable CVD process, an ALD process, a PVD process, and/or other suitable process.

As shown, a hard mask 21 is formed over the STI features 14. The STI hard mask 21 may be silicon nitride or other suitable material.

As further shown in FIGS. 13A-13B, the partially fabricated multi-gate device 100 further includes a sacrificial layer 17, such as a sacrificial or dummy gate structure 17 extending in the Y-direction. Sacrificial gate structures 17 are spaced from one another in the X-direction and are formed over portions of the fins 12 which are to be channel regions. The sacrificial gate structures 17 may extend over a number of adjacent fins 12 as shown. The sacrificial gate structures 17 lie directly over and define the channel regions of the GAA devices to be formed. Each of the sacrificial gate structures 17 may include a sacrificial gate dielectric and a sacrificial gate electrode over the sacrificial gate dielectric.

The sacrificial gate structures 17 are formed by first blanket depositing a sacrificial gate dielectric layer over the fins 12. A sacrificial gate electrode layer is then blanket deposited on the sacrificial gate dielectric layer and over the fins 12. The sacrificial gate dielectric layer includes silicon oxide, silicon nitride, or a combination thereof. The thickness of the sacrificial gate electrode layer is in a range from about 100 nm to about 200 nm in some embodiments. The sacrificial gate electrode layer includes silicon such as polycrystalline silicon or amorphous silicon. The thickness of the sacrificial gate dielectric layer is in a range from about 1 nm to about 5 nm in some embodiments. In some embodiments, the sacrificial gate structure 17 is subjected to a planarization operation. The sacrificial gate dielectric layer and the sacrificial gate electrode layer are deposited using CVD, including LPCVD and PECVD, PVD, ALD, or other suitable process. The sacrificial gate dielectric layer and the sacrificial gate electrode layer may be masked and patterned to form the sacrificial gate structures 17.

As shown, a mask layer 18 is formed over the sacrificial gate structures 17. The mask layer 18 may include a mask layer such as silicon oxide and a mask layer such as silicon nitride.

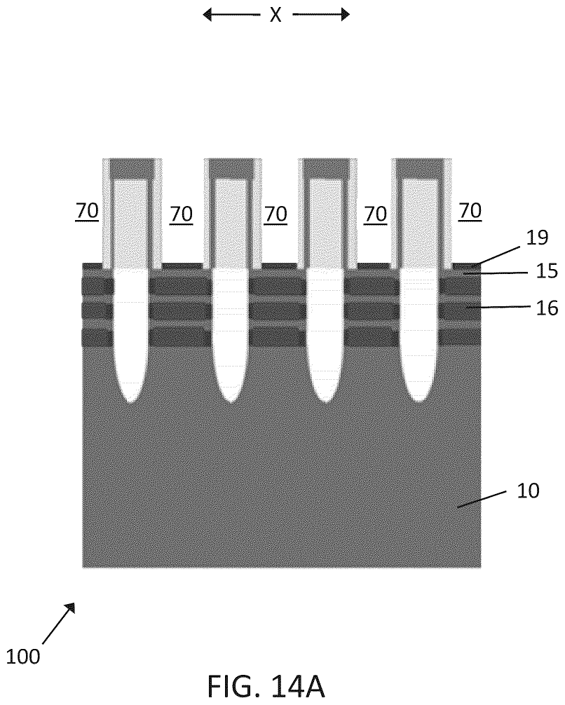

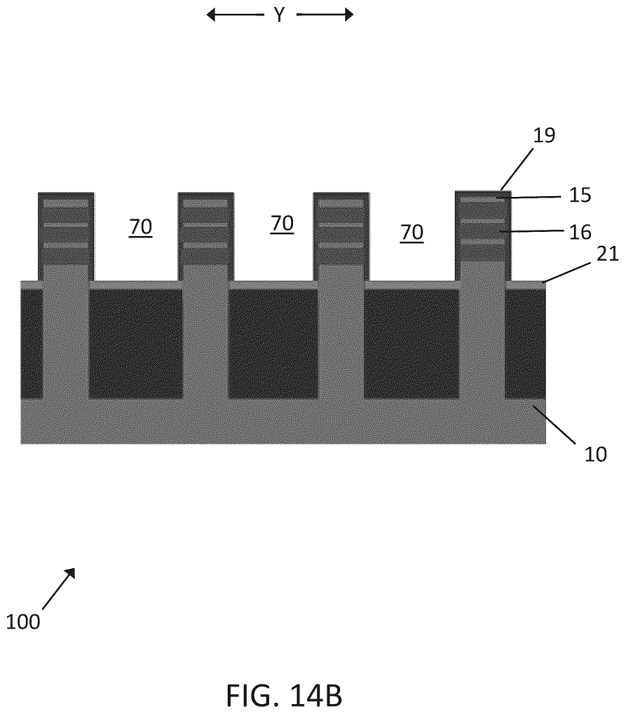

Cross-referencing FIGS. 12 and 14A-14B, method 200 may continue at block S210 with removing the sacrificial gate structures 17 to form gate cavities 70. The etch performed to remove the sacrificial gate structures 17 at block S210 lands on the liner 19 and the STI hard mask 21 such that the liner 19 remains over and surrounding the stack of layers 15 and 16 and the STI hard mask 21 remains covering the STI features 14.

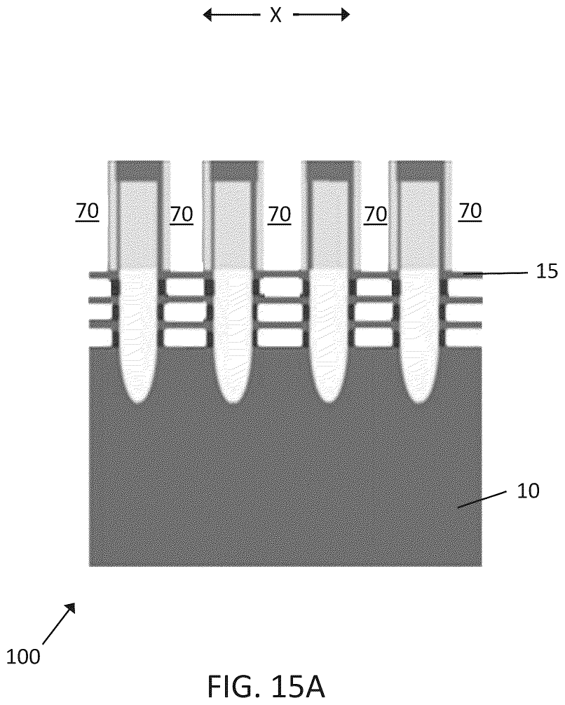

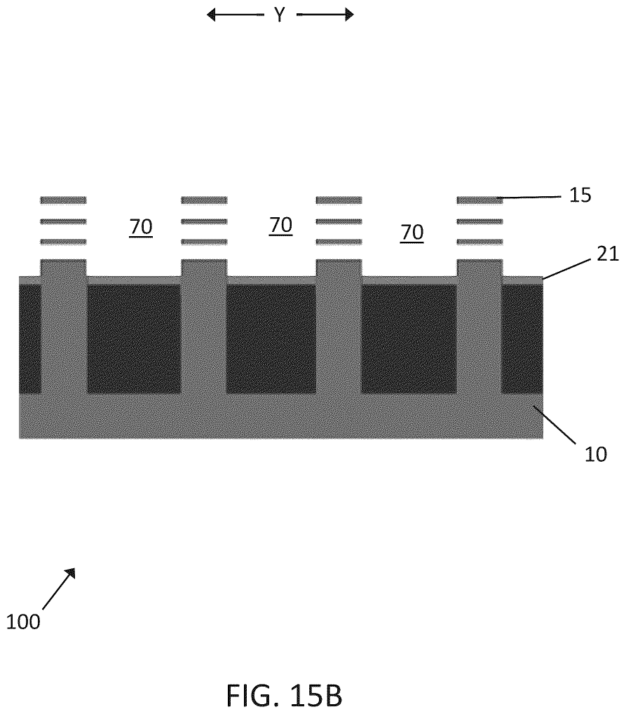

Cross-referencing FIGS. 12 and 15A-15B, method 200 may continue at block S212 with removing the interposer layers 16, leaving the nanosheet channel layers 15 spaced above the fins 12 to define the nanosheet channel regions. As shown, the etch performed at block S212 removes liner 19 before removing interposer layers 16. The etch performed at block S212 lands on the STI hard mask 21 such that the STI hard mask 21 remains covering the STI features 14.

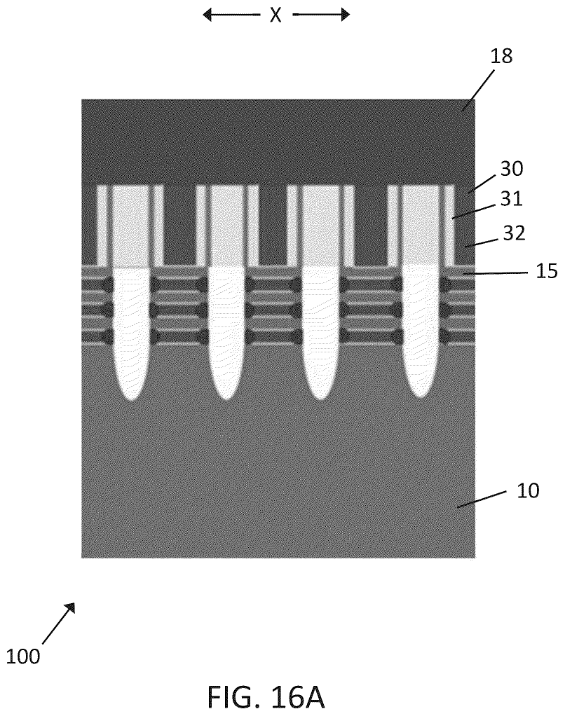

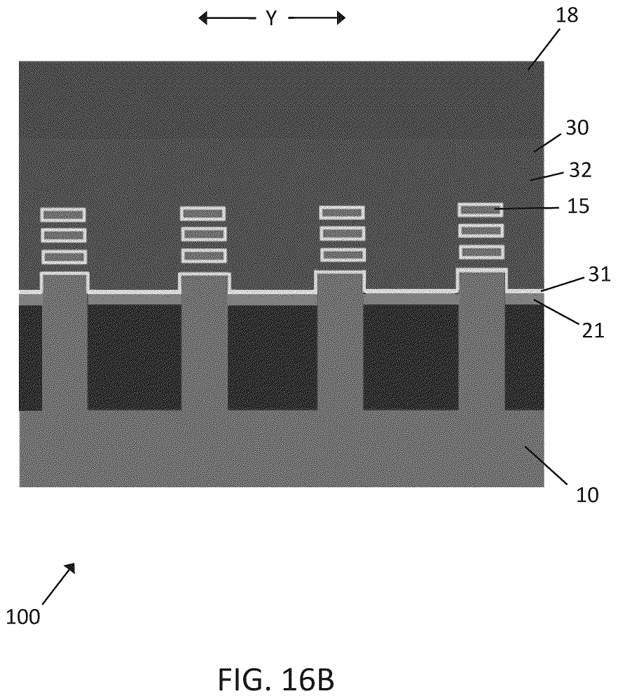

Cross-referencing FIGS. 12 and 16A-16B, method 200 may continue at block S212 with forming metal gates 30 in the gate cavities 70. Specifically, method 200 may include lining the gate cavities 70 with a dielectric liner 31. For example, a high-K gate dielectric layer 31 may be deposited along cavity sidewalls extending in the Y-direction, on the STI hard mask 21 at the cavity bottom, and around the nanosheet channel layers 15.

High-K gate dielectrics, as used and described herein, include dielectric materials having a high dielectric constant, for example, greater than that of thermal silicon oxide (about 3.9). An exemplary high-K gate dielectric layer 31 may include a high-K dielectric material such as hafnium oxide (HfO₂). Alternatively, the high-K gate dielectric layer 31 may include other high-K dielectric materials, such as TiO₂, HfZrO, Ta₂O₃, HfSiO₄, ZrO₂, ZrSiO₂, LaO, AIO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr) TiO₃ (BST), Al₂O₃, Si₃N₄, oxynitrides (SiON), combinations thereof, or other suitable material. The high-K gate dielectric layer 31 may be formed by ALD, physical vapor deposition (PVD), CVD, oxidation, and/or other suitable methods

Formation of the metal gates 30 further includes filling the gate cavities 70 with fill material 32. The fill material 32 may include multiple layers of a metal, metal alloy, or metal silicide. The fill material 32 may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the fill material 32 may include Ti, Ag, Al, TiAlN, TaC, TaCN, TaSiN, Mn, Zr, TiN, TaN, Ru, Mo, Al, WN, Cu, W, Re, Ir, Co, Ni, other suitable metal materials or a combination thereof. In various embodiments, the fill material 32 may be formed by ALD, PVD, CVD, e-beam evaporation, or other suitable process. Further, the fill material 32 may be formed separately for N-type and P-type transistors which may use different metal layers. In addition, the fill material 82 may provide an N-type or P-type work function, may serve as a transistor gate electrode, and in at least some embodiments, the fill material 32 may include a polysilicon layer. In some examples, the fill material 32 may include selectively-grown tungsten (W) and/or a fluorine-free tungsten (FFW) layer.

As shown in FIGS. 16A-16B, a chemical mechanical planarization (CMP) process may be performed to remove overburden portions of the liner 31 and fill material 32 to define the metal gates 30 in the gate cavities 70. As shown a mask layer 18 may be formed over the metal gate 30.

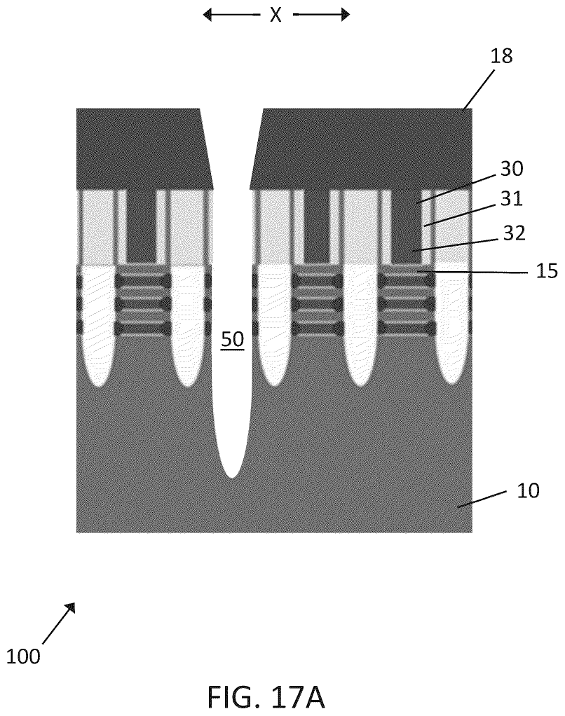

Cross-referencing FIGS. 12 and 17A-17B, method 200 may continue at block S204 with performing the CMODE etch process. Specifically, the mask layer is patterned before an etch is performed to remove a portion of the metal gate 30 overlying selected fins 12′ for removal. As a result, a trench 50 is formed. The etch process at block S204 may land on the liner 19 and the STI hard mask 21 such that the liner 19 remains over and surrounding the stack of layers 15 and 16 and the STI hard mask 21 remains covering the STI features 14. During the CMODE etch process, the uncovered liner 19 and underlying stack of layers 15 and 16 forming the portions of the selected fins 12′ are removed. As a result, trench 50 extends into the substrate 10.

The etch process at block S204 may land on the STI hard mask 21 such that the STI hard mask 21 remains covering the STI features 14.

As illustrated, method 200 includes removing a portion of at least one structure 12′ to form a trench 50. The trench 50 extends across the fins 12, i.e., in the Y-direction.

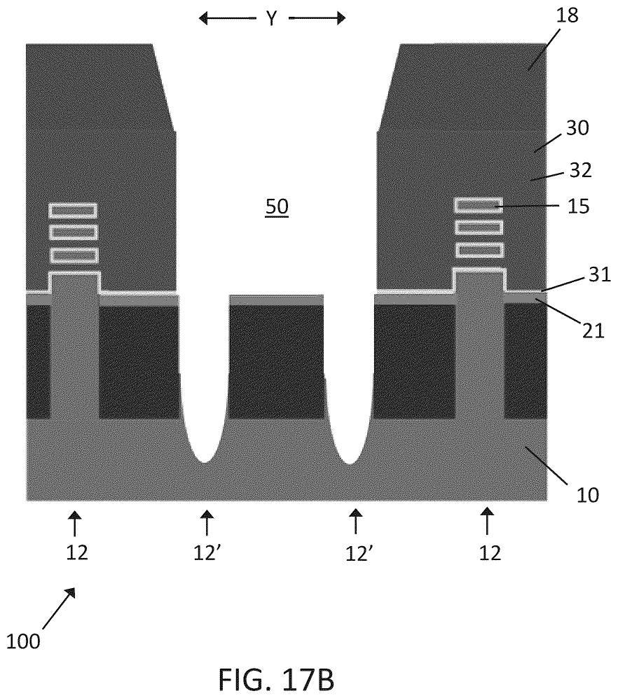

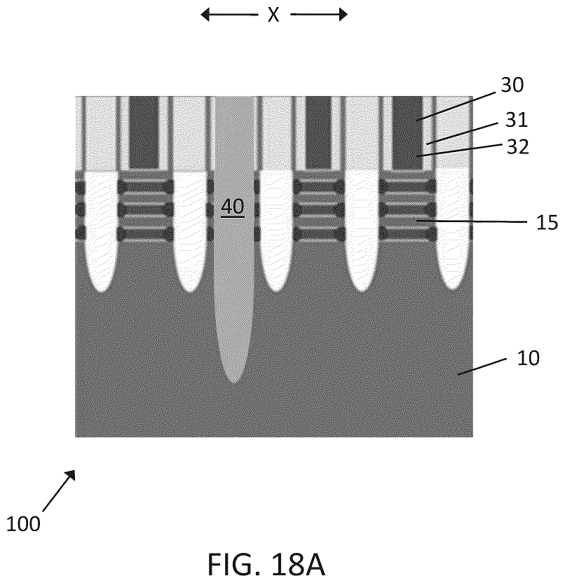

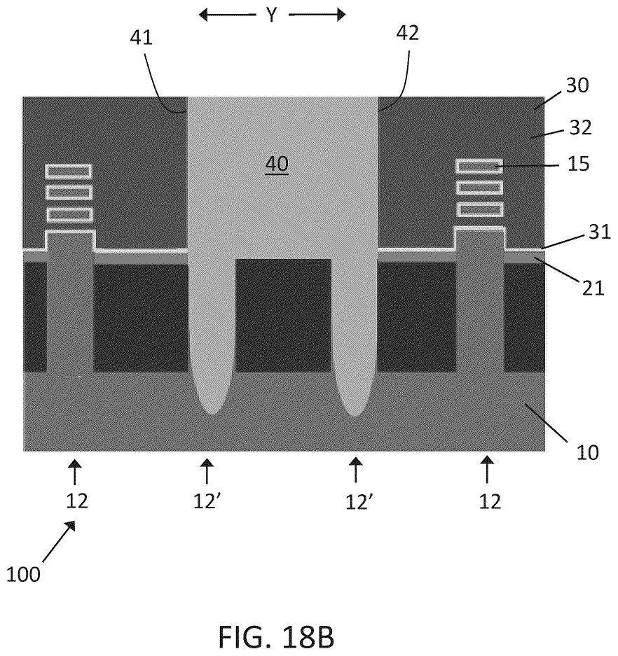

Cross-referencing FIGS. 12 and 18A-18B, method 200 may continue at block S208 with forming the CMODE insulation structure 40 in the trench. The CMODE insulation structure 40 may be formed by a fill material deposited in the trench 50. For example, the fill material may be silicon oxide. An overburden portion of the fill material may be removed by a planarization process.

As shown, the insulation structure 40 terminates at a first end wall 41, terminates at a second end wall 42, and extends in the Y-direction from the first end wall 41 to the second end wall 42.

As shown in FIG. 12, method 200 may continue at block S214 with further processing, such as performing middle end of line (MEOL) processing and back end of line (BEOL) processing.

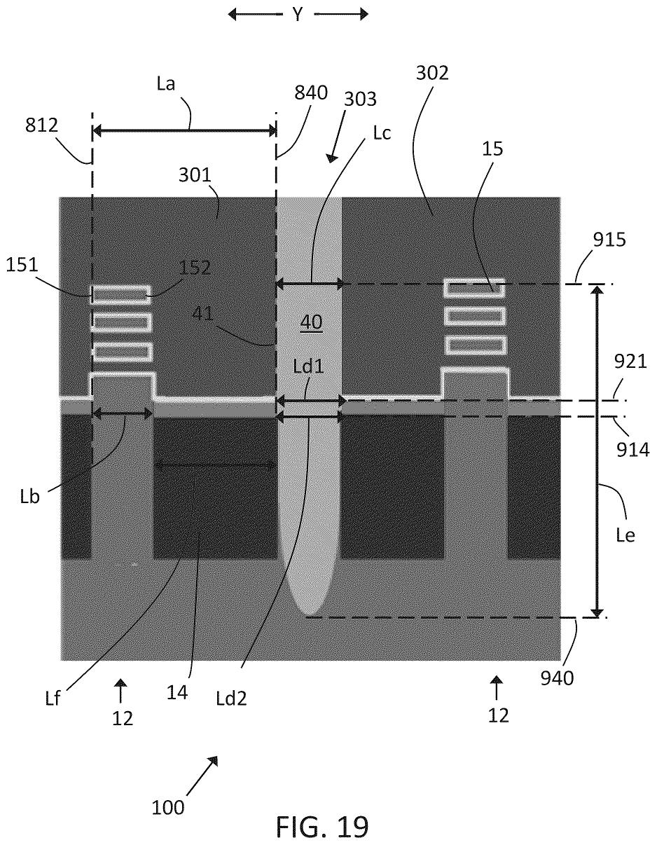

FIG. 19 is a Y-cut cross-sectional view, similar to FIG. 18B, illustrating an embodiment of an insulation structure 40 formed between two fins 12.

As shown in FIG. 19, the sidewall of a fin 12 defines a vertical plane 912, and the sidewall of the insulation structure 40 defines a vertical plane 840. As further shown, the upper surface of top nanosheet layer 15 defines an upper nanosheet plane 915, the upper surface of STI feature 14 defines an upper STI plane 914, the upper surface of STI hard mask 21 defines an upper STI plane 921, and the bottom trough point of insulation structure 40 defines a bottom-most plane 940.

As shown in FIG. 19, insulation structure 40 is formed with a pitch or horizontal distance La from plane 812 to plane 840. In certain embodiments, the pitch La is from 63.8 to 64.0 nanometers (nm), for example 63.9 nm.

As shown in FIG. 19, fin 12 is formed with a critical dimension or horizontal width Lb at plane 914. In certain embodiments, the critical dimension Lb is from 23.2 to 23.9 nm, for example 24.8 nm.

As shown in FIG. 19, insulation feature 60 is formed with a critical dimension or horizontal width Lc at plane 915. In certain embodiments, the critical dimension Lc is from 41.1 to 44.5 nm, for example 43.2 nm.

As shown in FIG. 19, insulation feature 60 is formed with a critical dimension or horizontal width Ld2 at plane 914. In certain embodiments, the critical dimension Ld2 is from 28.6 to 32.0 nm, for example 30.4 nm.

As shown in FIG. 19, insulation feature 60 is formed with a vertical depth Le from plane 915 to plane 940. In certain embodiments, the vertical depth Le is from 177.6 to 200.8 nm, for example 187.4 nm.

As shown in FIG. 19, side wall 152 of insulation feature 60 is distanced from the end wall 41 of the insulation structure 40 by a lateral distance Lf. In certain embodiments, the lateral distance Lf is at least 20 nm, such as at least 25 nm, at least 30 nm, at least 32 nm, at least 34 nm, at least 36 nm, at least 37 nm, at least 38 nm, at least 39 nm, at least 40 nm, at least 41 nm, at least 42 nm, at least 43 nm, at least 44 nm, or at least 45 nm. In certain embodiments, the lateral distance Lf is at most 22 nm, such as at most 25 nm, at most 30 nm, at most 32 nm, at most 34 nm, at most 36 nm, at most 37 nm, at most 38 nm, at most 39 nm, at most 40 nm, at most 41 nm, at most 42 nm, at most 43 nm, at most 44 nm, at most 45 nm, or at most 46 nm.

In certain embodiments, the critical dimension Lc is from 50% to 80% of the pitch La. For example, critical dimension Lc may be at least 50%, at least 51%, at least 52%, at least 53%, at least 54%, at least 55%, at least 56%, at least 57%, at least 58%, at least 59%, at least 60%, at least 61%, at least 62% at least 63%, at least 64%, at least 65%, at least 66%, at least 67%, at least 68%, at least 69%, or at least 70% of the pitch La. Further, critical dimension Lc may be at most 51%, at most 52%, at most 53%, at most 54%, at most 55%, at most 56%, at most 57%, at most 58%, at most 59%, at most 60%, at most 61%, at most 62%, at most 63%, at most 64%, at most 65%, at most 66%, at most 67%, at most 68%, at most 69%, at most 70%, at most 71%, at most 72%, at most 73%, at most 74%, at most 75%, at most 76%, at most 77%, at most 78%, at most 79%, or at most 80% of the pitch La.

In certain embodiments, the critical dimension Ld1 is from 30% to 70% of the pitch La. For example, critical dimension Ld1 may be at least 30%, at least 35%, at least 40%, at least 41%, at least 42%, at least 43%, at least 44%, at least 45%, at least 46%, at least 47%, at least 48%, at least 49%, at least 50%, at least 51%, at least 52%, at least 53%, at least 54%, or at least 55% of the pitch La. Further, critical dimension Ld1 may be at most 40%, at most 41%, at most 42%, at most 43%, at most 44%, at most 45%, at most 46%, at most 47%, at most 48%, at most 49%, at most 50%, at most 51%, at most 52%, at most 53%, at most 54%, at most 55%, or at most 56% of the pitch La.

In certain embodiments, the critical dimension Ld2 is from 20% to 60% of the pitch La. For example, critical dimension Ld2 may be at least 20%, at least 25%, at least 30%, at least 31%, at least 32%, at least 33%, at least 34%, at least 35%, at least 36%, at least 37%, at least 38%, at least 39%, at least 40%, at least 41%, at least 42%, at least 43%, at least 44%, or at least 45% of the pitch La. Further, critical dimension Ld2 may be at most 30%, at most 31%, at most 32%, at most 33%, at most 34%, at most 35%, at most 36%, at most 37%, at most 38%, at most 39%, at most 40%, at most 41%, at most 42%, at most 43%, at most 44%, at most 45%, or at most 46% of the pitch La.

The STI hard mask 21 has a vertical thickness from plane 914 to plane 921. In certain embodiments, the vertical thickness of the STI hard mask 21 is from 10.6 to 13.1 nm, such as 11.8 nm.

FIGS. 11-19 describe embodiments in which a CMODE process is performed to form the insulation structure 40 after the metal gate 30 is formed. In FIGS. 11-19, the gate dielectric liner 31 is not present on the end walls 41 and 42 of the insulation structure 40 (other than at the interface with the upper surface of STI hard mask 21.

Cross-referencing FIGS. 10 and 19, the device 100 is formed with an insulation structure 40 separating a first metal gate segment 301 and a second metal gate segment 302 formed by bisecting a common metal line 30. Thus, first metal gate segment 301 and second metal gate segment 302 are co-linear and extend away from the insulation structure 40 in a Y-direction. First metal gate segment 301 and second metal gate segment 302 are separated by a gap 303, in which the insulation feature 60 is formed.

While the above embodiments are described in relation to reducing or minimizing metal boundary effects at the interface between CPODE or CMODE insulation structures and metal gates, other embodiments are provided herein.

For example, certain embodiments are provided to controlling the metal gate boundary to control the channel length. Specifically, it has been found that inhomogeneous channel lengths in nanosheet transistors may be obtained due to the inter-diffusion of the interposer layers into the nanosheet channel layers. Such inter-diffusion may occur during activation of source/drain features by thermal treatments. In particular, high temperature annealing, e.g., at temperatures of at least 1000 degrees C., to activate source/drain carriers leads to inter-diffusion of interposer impurities through vacancy sites in nanosheet channel layers. Embodiments herein may avoid, reduce, and/or minimize inter-diffusion of the interposer layers into the nanosheet channel layers.

In certain embodiments, the interposer layers may be completely removed and replaced with protective liners. Such embodiments may be particularly useful for narrow or short nanosheet channel layers, i.e., nanosheet channel layers having a length of less than sixty (60) nanometers. In wide or long nanosheet channel layers, i.e., nanosheet channel layers having a length of at least sixty (60) nanometers, complete removal of the interposer layers may be difficult to achieve.

In certain embodiments, a protective liner is located at the interfaces between interposer layers and nanosheet channel layers. Such embodiments may be particularly useful for wide or long nanosheet channel layers, as the fierce interposer layer removal process is avoided.

Further, certain embodiments are provided to specifically avoid, reduce, and/or minimize inter-diffusion of the interposer layers into the nanosheet channel layers at the terminal regions of the nanosheet channel layers, i.e., regions adjacent to inner spacers such as the corners of the nanosheet channel layers. Specifically, the metal boundary length may be changed if terminal regions of the nanosheet channel layer are converted to inter-diffusion region and removed. Thus, protection of terminal regions of the nanosheet channel layers in particular may provide for formation of consistent metal boundaries.

To protect terminal regions of the nanosheet channel layers, certain embodiments use a protective layer with a hardness gradient. Specifically, terminal regions of the protective liner, i.e., regions adjacent to the inner spacers, are relatively hard, while a central region of the protective liner is relatively soft. As a result, during the thermal source/drain feature activation process, less inter-diffusion occurs in terminal regions of the nanosheet channel layer located under the hard terminal regions of the protection layer.

Also, certain embodiments provide for specifically avoiding, reducing, and/or minimizing inter-diffusion of the interposer layers into the nanosheet channel layers at the terminal regions of the nanosheet channel layers by controlling the shape of the inner spacers. Specifically, it has been found that providing inner spacers with convex profiles shields the terminal regions of the nanosheet layer and reduce inter-diffusion therein.

Certain embodiments provide for a pristine nanosheet channel and precise control of channel length. Such embodiments may use an oxide protective liner between the nanosheet channel layers and interposer layers to block interdiffusion through vacancy and interstitial sites.

Embodiments of the present disclosure offer advantages over the existing art, though it is understood that other embodiments may offer different advantages, not all advantages are necessarily discussed herein, and no particular advantage is required for all embodiments.

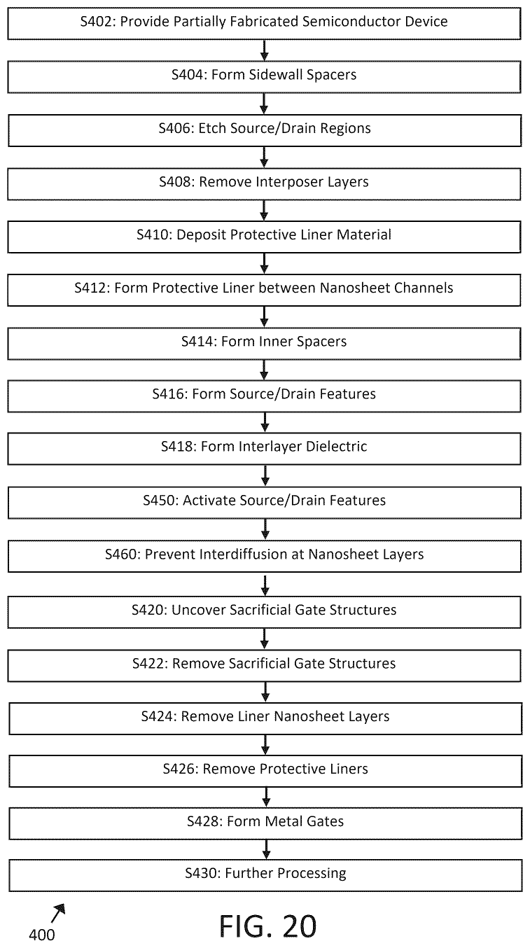

Referring to FIG. 20, illustrated therein is a method 400 of fabrication of a semiconductor device 100 (such as a multi-gate device) with reduced inter-diffusion, in accordance with various embodiments. Method 400 is discussed below with reference to a GAA device having a channel region that may be referred to as a nanosheet and which may include various geometries (e.g., cylindrical, bar-shaped) and dimensions. However, it will be understood that aspects of method 400, including the disclosed CPODE process, may be equally applied to other types of multi-gate devices without departing from the scope of the present disclosure. It is understood that method 400 includes steps having features of a complementary metal-oxide-semiconductor (CMOS) technology process flow and thus, are only described briefly herein. Also, additional steps may be performed before, after, and/or during method 400.

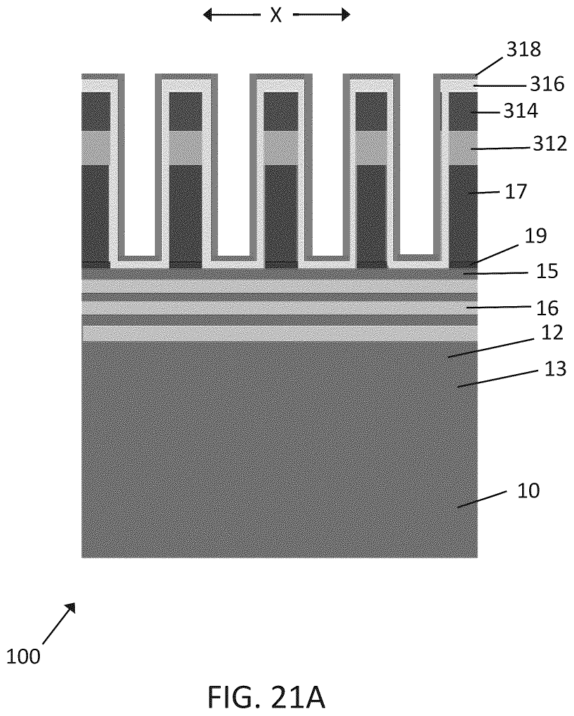

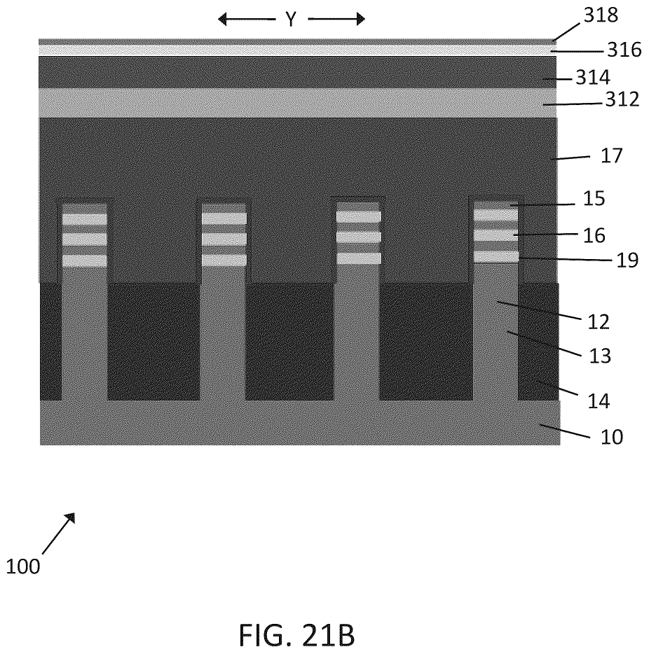

Method 400 is described below with reference to FIGS. 21-32 which illustrate the semiconductor device 100 at various stages of fabrication according to method 400. FIGS. 21A-32A provide cross-sectional views of an embodiment of the semiconductor device 100 along a plane substantially parallel to a plane defined by an X-axis through a fin. FIGS. 21B-32B provide cross-sectional views of an embodiment of the semiconductor device 100 along a plane substantially parallel to a plane defined by an Y-axis through a gate.

The semiconductor device 100 may include various other devices and features, such as other types of devices such as additional transistors, bipolar junction transistors, resistors, capacitors, inductors, diodes, fuses, static random-access memory (SRAM) and/or other logic circuits, etc., but is simplified for a better understanding of the inventive concepts of the present disclosure. In some embodiments, the semiconductor device 100 includes a plurality of semiconductor devices (e.g., transistors), including PFETs, NFETs, etc., which may be interconnected. Moreover, it is noted that the process steps of method 400, including any descriptions given with reference to the figures are merely exemplary and are not intended to be limiting beyond what is specifically recited in the claims that follow.

Method 400 begins at block S402 where a partially fabricated multi-gate device 100 is provided. Referring to the example of FIGS. 21A-21B, in an embodiment of block S402, the method 400 forms structures 12, such as fins 12, over the substrate 10. The fins 12 extend in the X-direction and are distanced apart from one another in the Y-direction perpendicular to the X-direction. In some embodiments, the substrate 10 may be a semiconductor substrate such as a silicon substrate. The substrate 10 may include various layers, including conductive or insulating layers formed on a semiconductor substrate. The substrate 10 may include various doping configurations depending on design requirements as is known in the art. The substrate 10 may also include other semiconductors such as germanium, silicon carbide (SiC), silicon germanium (SiGe), or diamond. Alternatively, the substrate 10 may include a compound semiconductor and/or an alloy semiconductor. Further, the substrate 10 may optionally include an epi layer, may be strained for performance enhancement, may include a silicon-on-insulator (SOI) structure, and/or have other suitable enhancement features.

The fins 12 may include nanosheet channel layers, collectively identified by reference number 15, interleaved with interposer layers, collectively identified by reference number 16. In some embodiments, the nanosheet channel layers 15 may include silicon (Si) and interposer layers 16 may include silicon germanium (SiGe). However, in some embodiments, the nanosheet channel layers 15 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. In such embodiments, the interposer layers 16 may include silicon (Si) or another material different from the material of the nanosheet channel layers 15. By way of example, the nanosheet channel layers 15 may be epitaxially grown by a molecular beam epitaxy (MBE) process, a metalorganic chemical vapor deposition (MOCVD) process, and/or other suitable epitaxial growth processes.

As shown, a liner 19 may be formed along sidewalls and over the top of the stack of layers 15 and 16. An exemplary liner 19 is silicon oxide.

In various embodiments, each of the fins 12 includes a substrate portion 13 formed from the substrate 10. It is noted that while the fins 12 are illustrated as including three (3) nanosheet channel layers 15, this is for illustrative purposes only and is not intended to be limiting beyond what is specifically recited in the claims. It can be appreciated that any number of nanosheet channel layers 15 can be formed, where for example, the number of nanosheet channel layers 15 depends on the desired number of channels regions for the GAA device (e.g., the device 100). In some embodiments, the number of nanosheet channel layers 15 is between three and ten.

Shallow trench isolation (STI) features 14 may also be formed interposing the fins 12. In some embodiments, the STI features 14 include SiO₂, silicon nitride, silicon oxynitride, fluorine-doped silicate glass (FSG), a low-k dielectric, combinations thereof, and/or other suitable materials known in the art. In various examples, the dielectric layer used to form the STI features may be deposited by a CVD process, a subatmospheric CVD (SACVD) process, a flowable CVD process, an ALD process, a PVD process, and/or other suitable process.

As further shown in FIGS. 21A-21B, the partially fabricated multi-gate device 100 further includes sacrificial layers 17, such as sacrificial or dummy gate structures 17 extending in the Y-direction. Sacrificial gate structures 17 are spaced from one another in the X-direction and are formed over portions of the fins 12 which are to be channel regions. The sacrificial gate structures 17 may extend over a number of adjacent fins 12. The sacrificial gate structures 17 lie directly over and define the channel regions of the GAA devices to be formed. Each of the sacrificial gate structures 17 may include a sacrificial gate dielectric and a sacrificial gate electrode over the sacrificial gate dielectric.

The sacrificial gate structures 17 are formed by first blanket depositing a sacrificial gate dielectric layer over the fins 12. A sacrificial gate electrode layer is then blanket deposited on the sacrificial gate dielectric layer and over the fins 12. The sacrificial gate dielectric layer includes silicon oxide, silicon nitride, or a combination thereof. The thickness of the sacrificial gate electrode layer is in a range from about 100 nm to about 200 nm in some embodiments. The sacrificial gate electrode layer includes silicon such as polycrystalline silicon or amorphous silicon. The thickness of the sacrificial gate dielectric layer is in a range from about 1 nm to about 5 nm in some embodiments. In some embodiments, the sacrificial gate structures 17 are subjected to a planarization operation. The sacrificial gate dielectric layer and the sacrificial gate electrode layer are deposited using CVD, including LPCVD and PECVD, PVD, ALD, or other suitable process. The sacrificial gate dielectric layer and the sacrificial gate electrode layer may be masked with mask layers 312 and 314 and patterned to form the sacrificial gate structures 17.

At operation S404, method 400 further includes forming sidewall spacers by depositing a low-K spacer 316 over the sacrificial gate structures 17 as shown. Further, a dielectric layer 318, such as a silicon nitride layer, may be deposited over the low-K spacer 316.

Cross-referencing FIGS. 20 and 22A-22B, method 400 may continue at block S406 etching source/drain regions. Specifically, the portions of the layers 15 and 16 and the underlying substrate 10 that are not covered by sacrificial gate structures 17 are directionally etch to form source/drain region cavities 320 in each fin 12. Horizontal portions of dielectric layer 318 and low-K spacer 316 are also removed, such as in locations between sacrificial gate structures 17 and over sacrificial gate structures 17 while remaining on sidewalls of the sacrificial gate structures 17.

Cross-referencing FIGS. 20 and 23A-23B, method 400 may continue at block S408 with removing the interposer layers 16 to form voids 322, leaving the nanosheet channel layers 15 spaced above the fins 12 to define the nanosheet channel regions. For example, an etch may be performed through cavities 320 to selectively etch the interposer layers 16.

Cross-referencing FIGS. 20 and 24A-24B, method 400 may continue at block S410 with depositing a protective liner material 328. In exemplary embodiments, the protective liner material 328 is conformally deposited along the exposed surfaces of the structure of device 100, such as along the sidewalls of the cavity 320. As shown, the protective liner material 328 fills the voids 322.

In certain embodiments, the protective liner material 328 is silicon oxide and/or silicon nitride.

Cross-referencing FIGS. 20 and 25A-25B, method 400 may continue at block S412 with forming a protective liner 330 from the protective liner material 328. For example, the protective liner material 328 may be trimmed and removed from the sidewalls of the cavity 320 and from the upper surface of the structure of device 100 such that the protective liner material 328 remains in the voids 322 between nanosheet layers 15 as protective liners 330. Further, block S412 may include recessing side surfaces 333 of the protective liners 330.

Cross-referencing FIGS. 20 and 26A-26B, method 400 may continue at block S414 with forming inner spacers 340 adjacent to the protective liners 330. For example, an inner spacer material may be formed on the protective liners 330. Excess material extending into the cavities 320 may be trimmed. Thus, the inner spacers 340 are formed. The inner spacers 340 separate the protective liners 330 from the cavities 320.

Cross-referencing FIGS. 20 and 27A-27B, method 400 may continue at block S416 with forming source/drain features 350 in the cavities 320. For example, epitaxial material may be grown on the substrate 10 and nanosheet layers 15.

Cross-referencing FIGS. 20 and 28A-28B, method 400 may continue at block S418 with forming interlayer dielectric (ILD) 360 over the source/drain features 350. Block S418 may include planarizing the ILD 360, such as to an upper surface formed with mask layer 314.

As shown in FIG. 20, method 400 may include, at block S450, performing a process to activate the source/drain features 350. In certain embodiments, the process at block S450 may be a high temperature anneal process. For example, the high temperature anneal process may be performed at a temperature of at least 1000 degrees C. In other embodiments, the process at block S419 may be a low temperature anneal process. For example, the low temperature anneal process may be performed at a temperature of less than 1000 degrees C.

During the anneal process, method 400 includes, at block S460, preventing interdiffusion in the nanosheet layers 15. Specifically, the protective liner 330 forms a barrier against diffusion of impurities, such as from SiGe or Ge, through vacancy sites in the nanosheet layers 15.

Cross-referencing FIGS. 20 and 29A-29B, method 400 may continue at block S420 with uncovering the sacrificial gate structures 17. Block S420 may include performing a planarization process to remove the mask layers 312 and 314.

Cross-referencing FIGS. 20 and 30A-30B, method 400 may continue at block S422 with removing the sacrificial gate structures 17 to form gate cavities 370.

Cross-referencing FIGS. 20 and 31A-31B, method 400 may continue at block S424 with removing the liner 19 from the sidewalls and over the top of the stack of layers 15 and protective liners 330.

Cross-referencing FIGS. 20 and 32A-32B, method 400 may continue at block S426 with removing the protective liners 330 from between the nanosheet channel layers 15, such as in a sheet release process.

Cross-referencing FIGS. 20 and 33A-33B, method 400 may continue at block S428 with forming metal gates 380 in the gate cavities 370. Specifically, method 400 may include lining the gate cavities 370 with a dielectric liner 381. For example, a high-K gate dielectric layer 381 may be deposited along cavity sidewalls, on the STI hard mask 21 at the cavity bottom, and around the nanosheet channel layers 15.

High-K gate dielectrics, as used and described herein, include dielectric materials having a high dielectric constant, for example, greater than that of thermal silicon oxide (about 3.9). An exemplary high-K gate dielectric layer 381 may include a high-K dielectric material such as hafnium oxide (HfO₂). Alternatively, the high-K gate dielectric layer 381 may include other high-K dielectric materials, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr) TiO₃ (BST), Al₂O₃, Si₃N₄, oxynitrides (SiON), combinations thereof, or other suitable material. The high-K gate dielectric layer 381 may be formed by ALD, physical vapor deposition (PVD), CVD, oxidation, and/or other suitable methods.

Formation of the metal gates 380 further includes filling the gate cavities 370 with fill material 382. The fill material 382 may include multiple layers of a metal, metal alloy, or metal silicide. The fill material 382 may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the fill material 382 may include Ti, Ag, Al, TiAlN, TaC, TaCN, TaSiN, Mn, Zr, TiN, TaN, Ru, Mo, Al, WN, Cu, W, Re, Ir, Co, Ni, other suitable metal materials or a combination thereof. In various embodiments, the fill material 382 may be formed by ALD, PVD, CVD, e-beam evaporation, or other suitable process. Further, the fill material 382 may be formed separately for N-type and P-type transistors which may use different metal layers. In addition, the fill material 382 may provide an N-type or P-type work function, may serve as a transistor gate electrode, and in at least some embodiments, the fill material 382 may include a polysilicon layer. In some examples, the fill material 382 may include selectively-grown tungsten (W) and/or a fluorine-free tungsten (FFW) layer.

As shown in FIGS. 33A-33B, a chemical mechanical planarization (CMP) process may be performed to remove overburden portions of the liner 381 and fill material 382 to define the metal gates 380 in the gate cavities 370.

As shown in FIG. 20, method 400 may continue at block S430 with further processing, such as performing middle end of line (MEOL) processing and back end of line (BEOL) processing.

While in the embodiments of FIGS. 20-33B the interposer layers 16 are completely removed and replaced with protective liners 330, other embodiments may provide for the use of protective liners 330 formed around interposer layers 16.

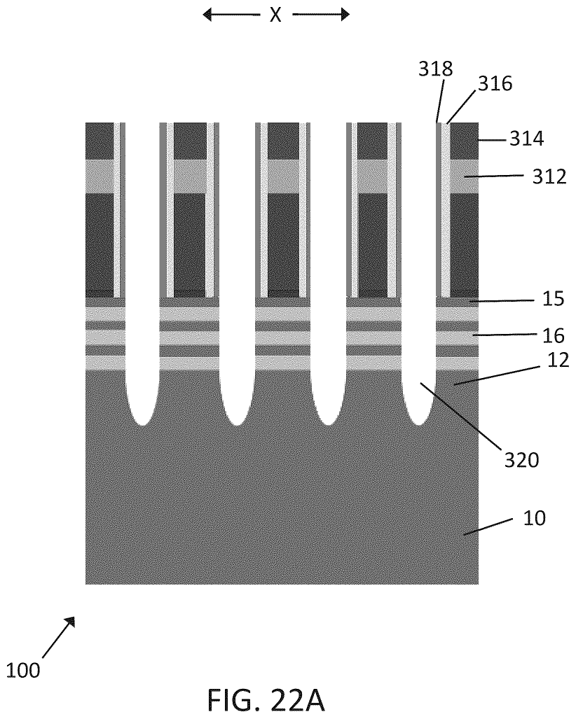

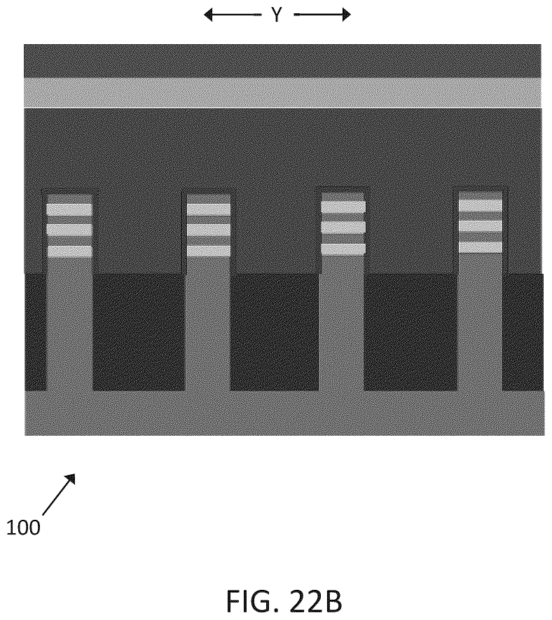

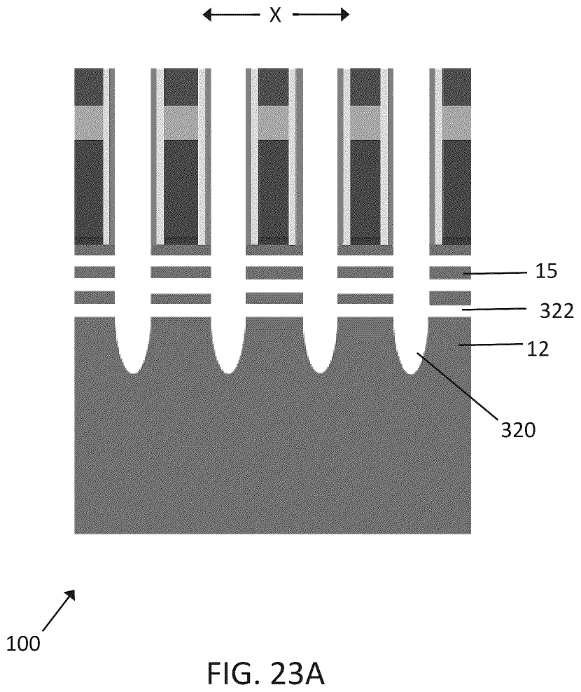

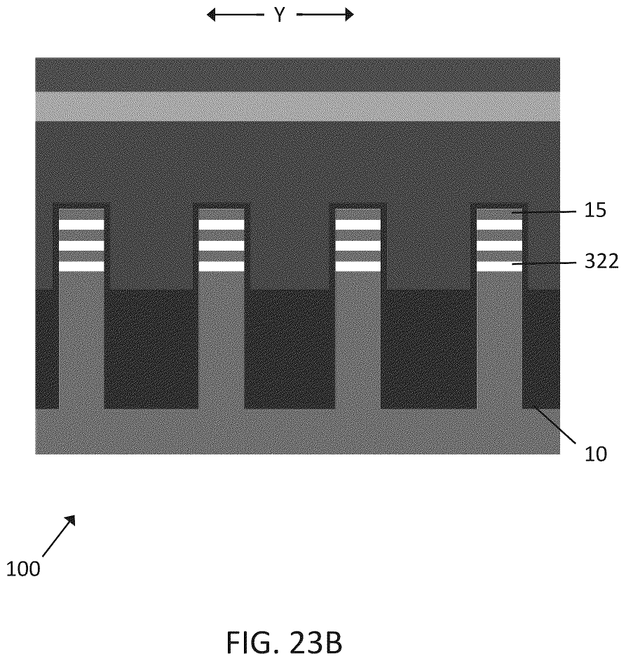

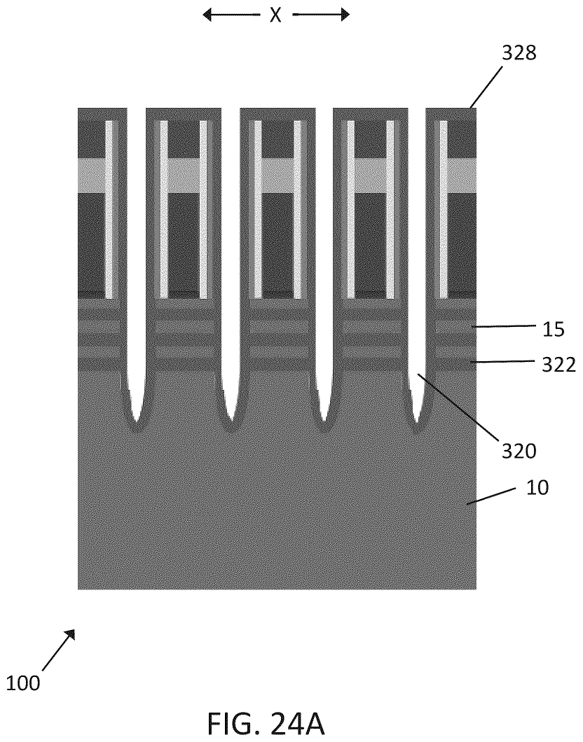

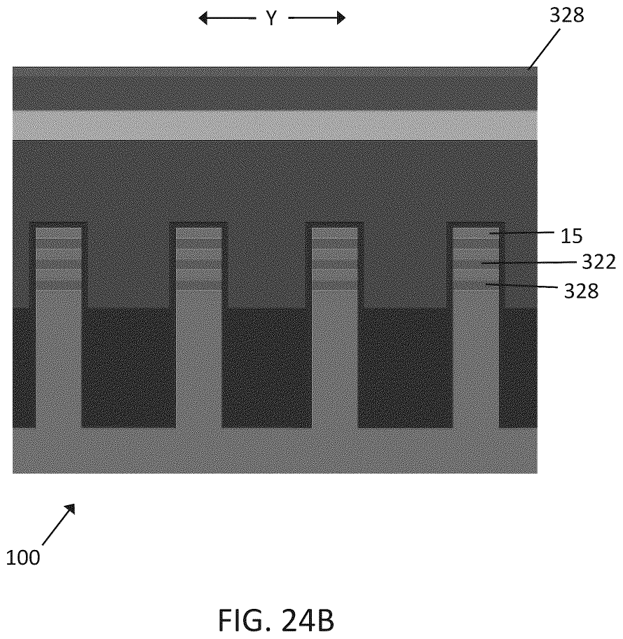

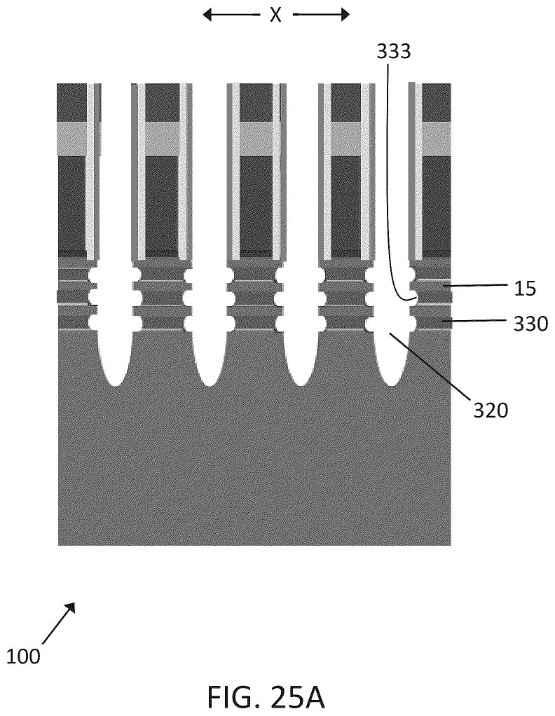

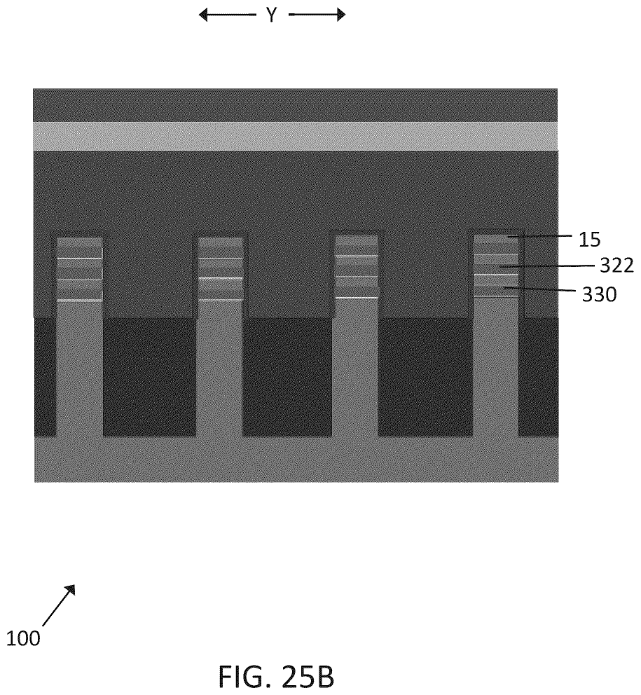

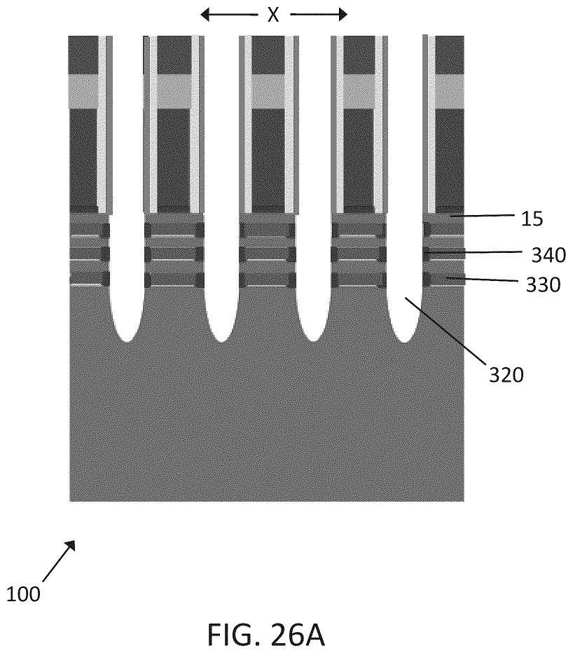

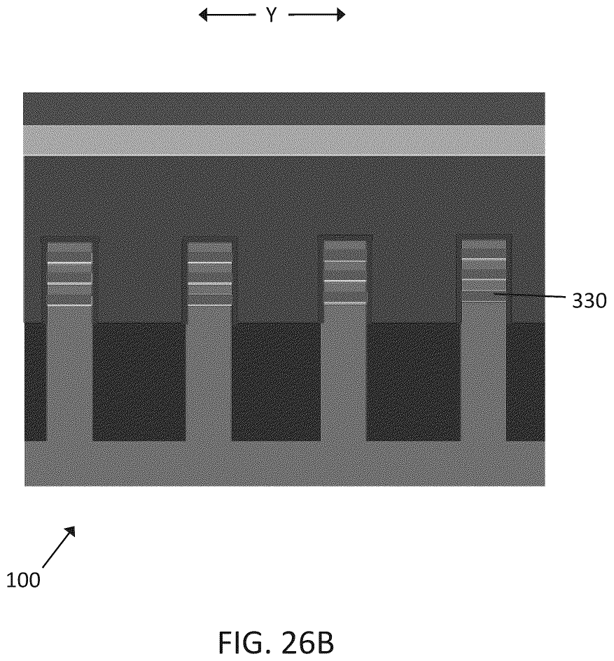

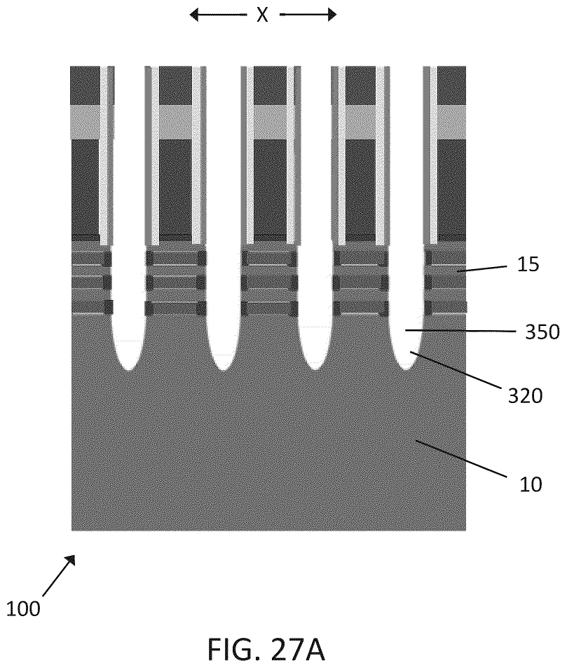

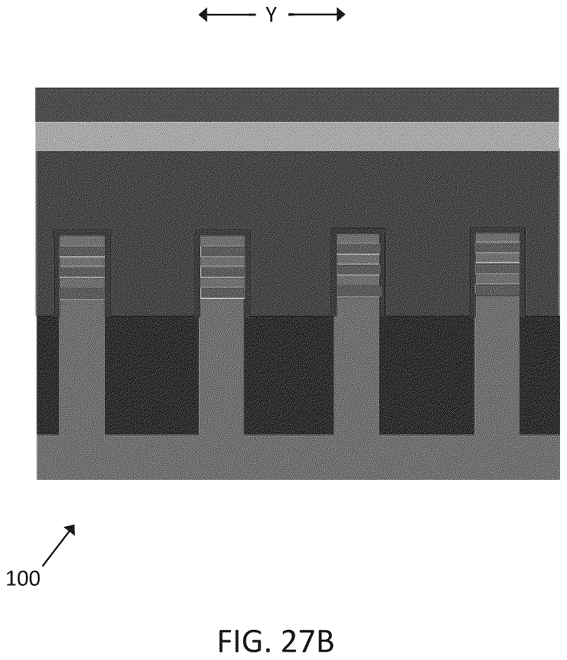

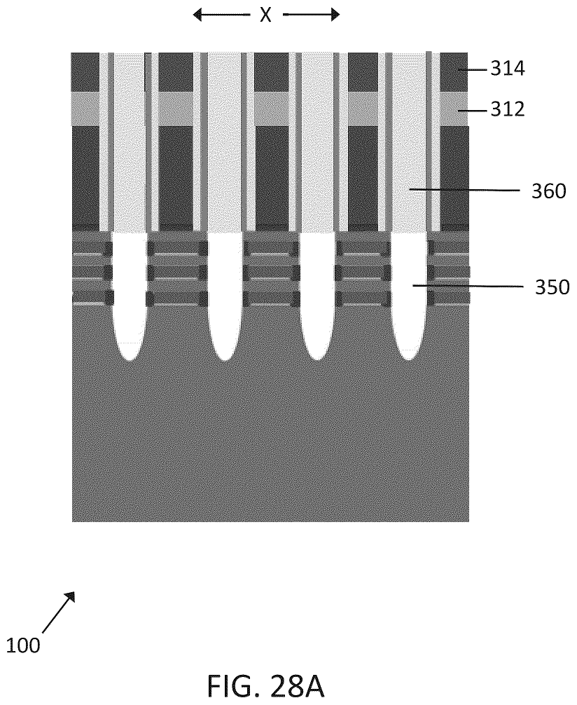

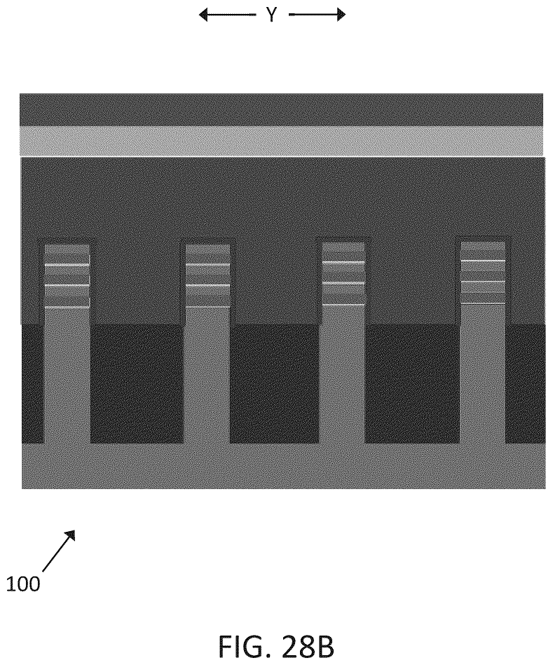

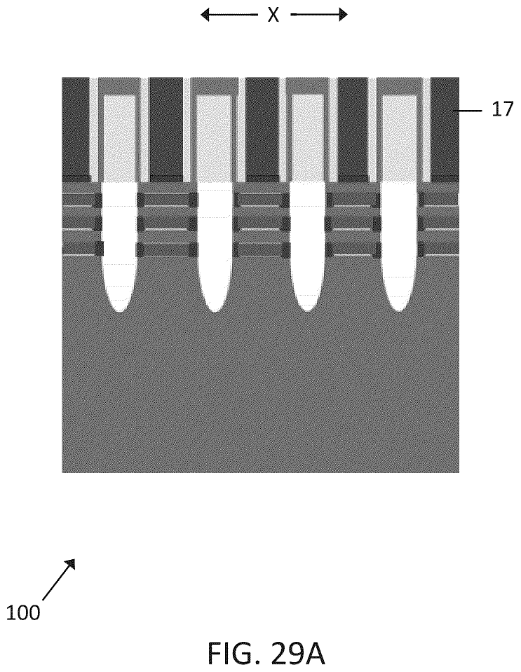

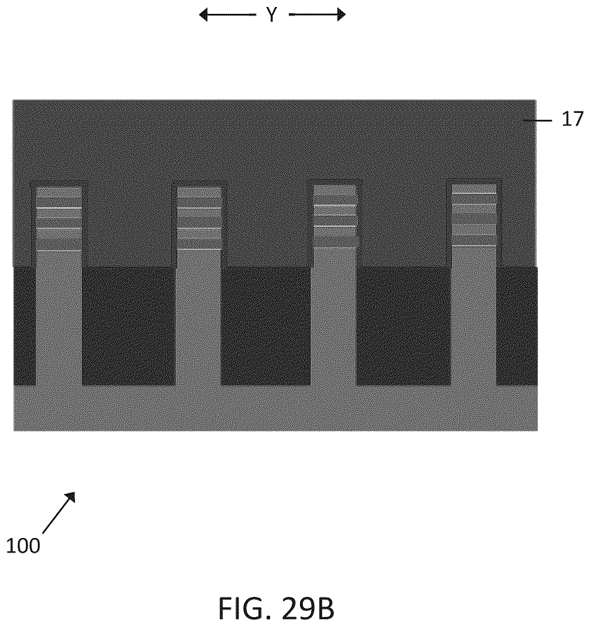

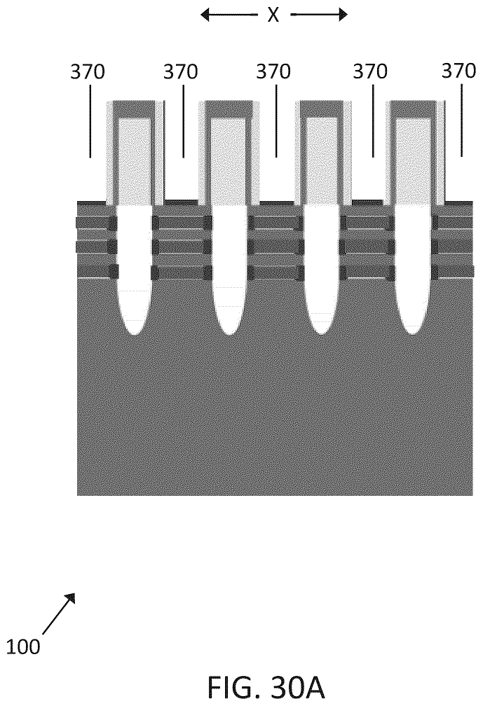

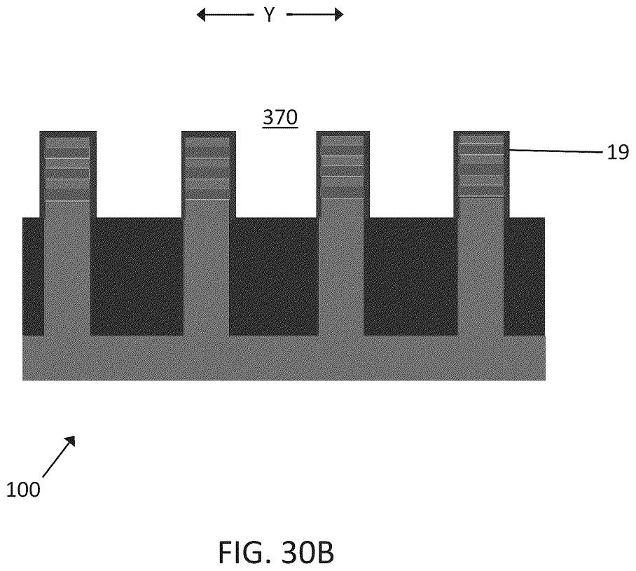

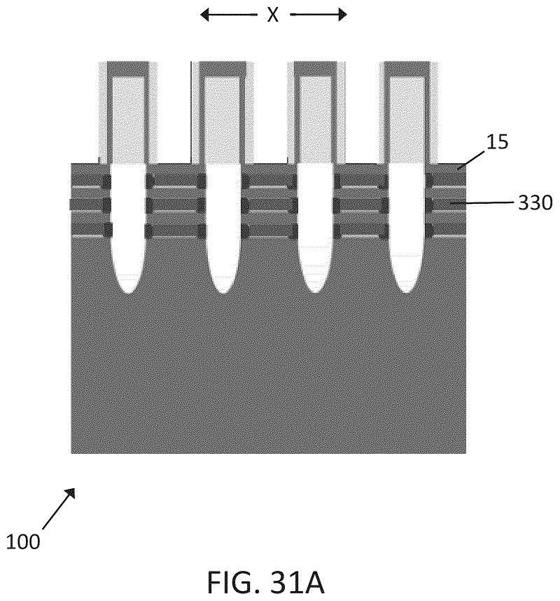

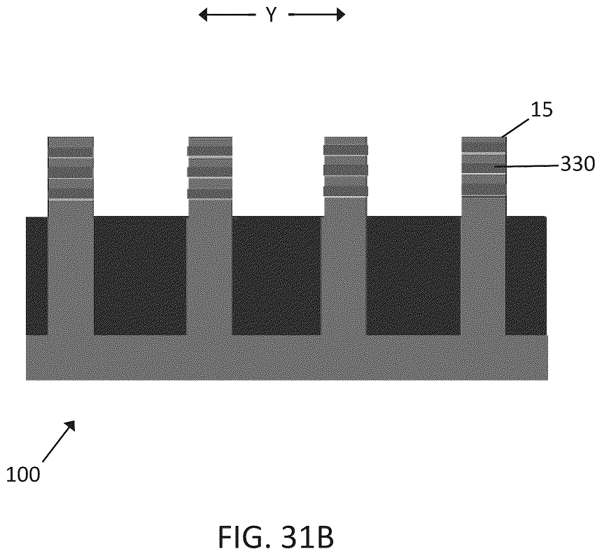

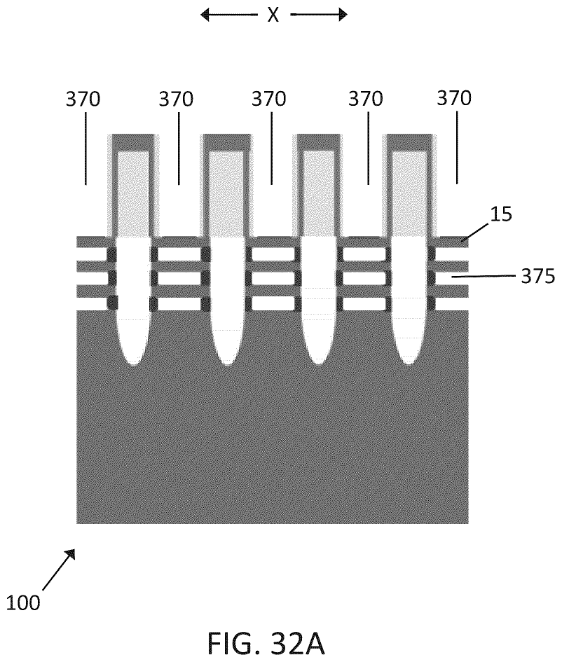

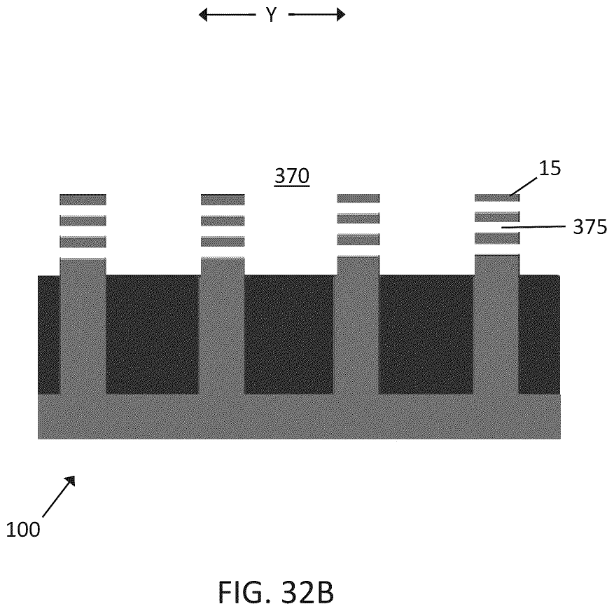

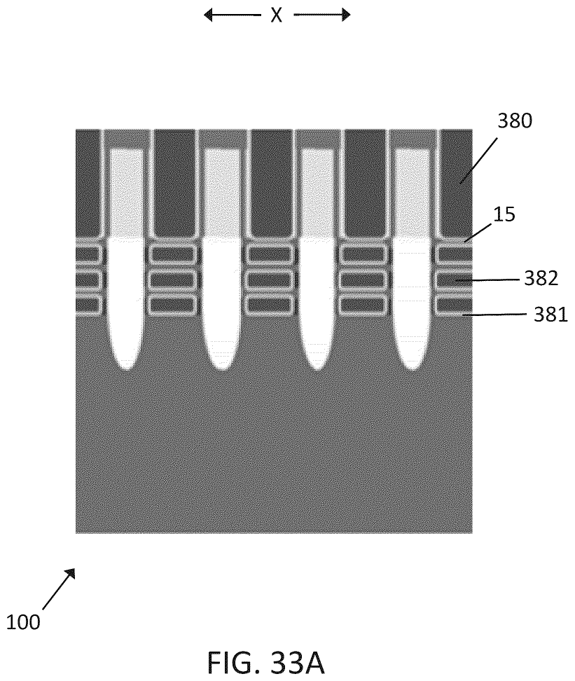

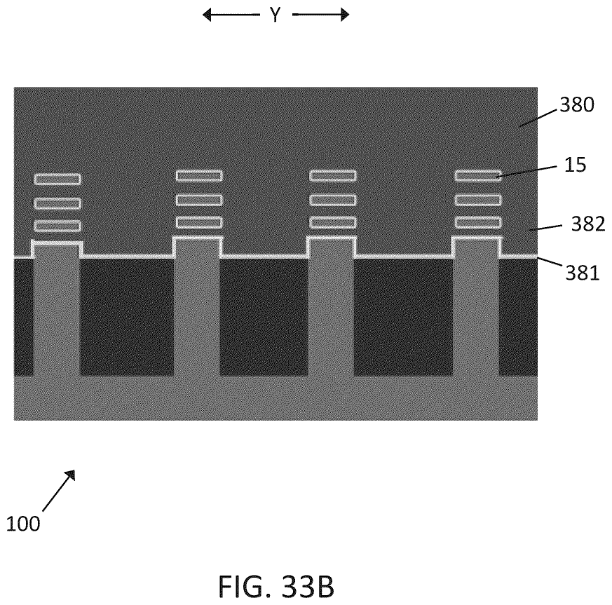

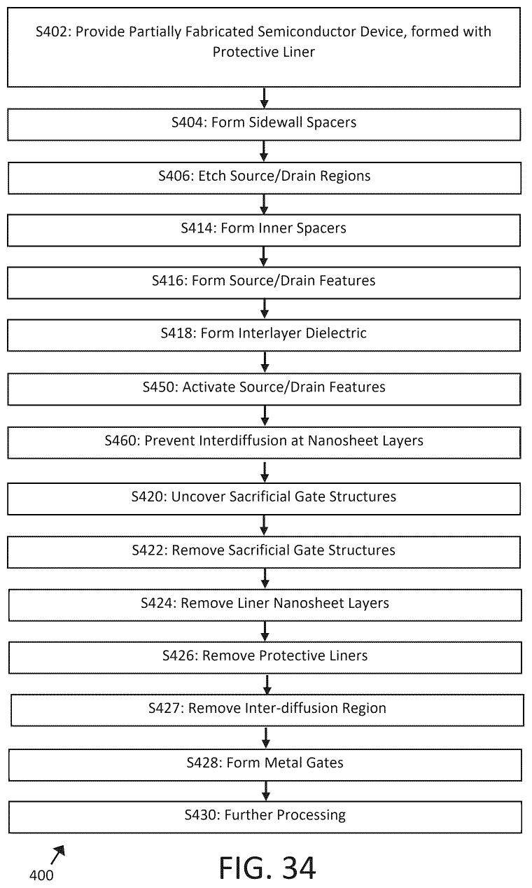

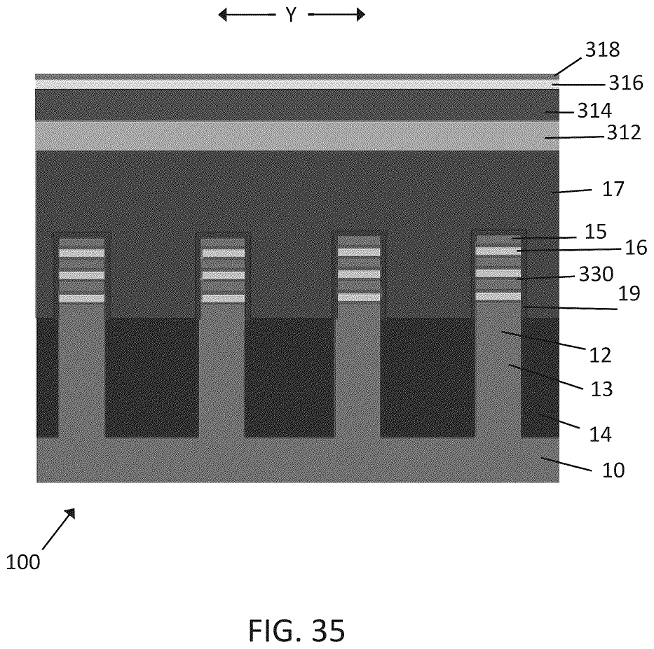

For example, referring to FIG. 34, method 400 is illustrated in accordance with such an embodiment. FIG. 34 describes method 400 in conjunction with FIGS. 35-41, which are all Y-cut cross-sectional views.

Cross-referencing FIGS. 34 and 35, method 400 includes providing a partially fabricated multi-gate device 100 as described above.

However, in the embodiment of FIG. 34, block S402 includes performing blocks S410 and S412, i.e., depositing and forming a protective liner 330 between interposer layers 16 and the nanosheet layers 15. Thus, the fins 12 may include nanosheet channel layers 15, interleaved with protective liners 330, and interleaved with interposer layers 16. In some embodiments, the nanosheet channel layers 15 may include silicon (Si) and interposer layers 16 may include silicon germanium (SiGe). However, in some embodiments, the nanosheet channel layers 15 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. In such embodiments, the interposer layers 16 may include silicon (Si) or another material different from the material of the nanosheet channel layers 15. By way of example, the nanosheet channel layers 15 may be epitaxially grown by a molecular beam epitaxy (MBE) process, a metalorganic chemical vapor deposition (MOCVD) process, and/or other suitable epitaxial growth processes. The protective liners 300 may be formed from silicon oxide, silicon nitride, or another suitable material for inhibiting interdiffusion of material from interposer layers 16 into nanosheet channel layers 15.

As shown in FIG. 35, each protective liner 330 is located between the interposer layers 16 and the nanosheet layers 15. The stack of layers may be formed over the substrate portion 13 of fin 12 as a stack of liner 330, layer 16, liner 330, layer 15, liner 330, and so on until the uppermost layer, such as uppermost layer 15.

FIG. 36 is a partial view of the cross-section of FIG. 35, focused on the layers 15 and 16 and protective liner 330. As shown, the protective liner 330 completely separates layer 15 from layer 16, i.e., no portion of layer 16 contacts layer 15.

In certain embodiments, the protective liner 330 is silicon oxide.

As shown in FIG. 35, a liner 19 may be formed along sidewalls and over the top of the stack of layers 15 and 16 and liners 330.

Shallow trench isolation (STI) features 14 may also be formed interposing the fins 12 as described above.

As further shown in FIG. 35, sacrificial or dummy gate structures 17 are formed over the fins 12 as described above.

At operation S404, method 400 further includes forming sidewall spacers by depositing a low-K spacer over the sacrificial gate structures 17. Further, a dielectric layer, such as a silicon nitride layer, may be deposited over the low-K spacer, as described above.

In the embodiment of FIG. 34, method 400 continues at block S406 with etching source/drain regions as described above.

In the embodiment of FIG. 34, method 400 continues at block S414 with forming inner spacers adjacent to the interposer layers 16 and protective liners 330. For example, a sidewall surfaces of the interposer layers 16 and protective liners 330, uncovered when etching the source/drain regions, may be recessed. Then, an inner spacer material may be deposited and trimmed to form the inner spacers as described above.

In the embodiment of FIG. 34, method 400 continues at block S416 with forming source/drain features in the cavities as described above. Further, method 400 may continue at block S418 with forming interlayer dielectric (ILD) over the source/drain features as described above.

FIG. 37 is a partial view, similar to FIG. 36, illustrating the structure of the device 100 after formation of the inner spacers 340 and source/drain features 350. As shown, the protective liner 330 extends from inner spacer 340 to inner spacer 340 and completely separates layer 15 from layer 16, i.e., no portion of layer 16 contacts layer 15.

Further, the protective liner 330 is formed with a thickness H_{L}. Also, the nanosheet channel layer 15 contacts the inner spacer 340 at interfaces 345. Each interface 345 independently has a length L1.

As shown in FIG. 34, method 400 includes, at block S450, performing a process to activate the source/drain features. In certain embodiments, the process at block S450 may be a high temperature anneal process. For example, the high temperature anneal process may be performed at a temperature of at least 1000 degrees C. In other embodiments, the process at block S419 may be a low temperature anneal process. For example, the low temperature anneal process may be performed at a temperature of less than 1000 degrees C.

During the anneal process, method 400 includes, at block S460, preventing or reducing interdiffusion in the nanosheet layers 15. Specifically, the protective liner 330 forms a barrier against diffusion of impurities, such as from SiGe or Ge from interposer layer 16, through vacancy sites in the nanosheet layers 15.

Thus, during the anneal process of block S450, the protective liner prevents interdiffusion of material from the interposer layers 16 (such as germanium or silicon germanium) into the nanosheet layers 15.

FIG. 38 is a partial view, similar to FIG. 37, illustrating the structure of the device 100 after blocks S450 and block S460. FIG. 39 is a view focused on a portion of the device 100 of FIG. 38. Specifically, focused on the corner 399 where the protective liner 330 contacts the inner spacer 340.

As most clearly shown in FIG. 39, an inter-diffusion region 390 is formed in the nanosheet channel layer 15 under the protective layer 300, wherein material from the interposer layer 16 inter-diffuses into the nanosheet channel layer 15. The inter-diffusion region 390 is not present under the inner spacer 340, i.e., has a thickness of zero under the inner spacer 340, and grows to a maximum thickness H_{D} such as at a maximum distance from the inner spacer 340, i.e., at a midpoint between opposite inner spacers 340.

Cross-referencing FIGS. 37 and 39, the thickness H_{L} and thickness H_{D} are inversely related. For example, when the protective liner 330 is not present and thickness H_{L} is zero, then the inter-diffusion region 390 is a largest size and thickness H_{D} is at a maximum. When thickness H_{L} is very large, thickness H_{D} may be zero.

The embodiment of FIG. 34 may continue with uncovering the sacrificial gate structures 17 at block S420, removing the sacrificial gate structures 17 to form gate cavities at block S422, removing the liner 19 from the sidewalls and over the top of the stack of layers 15, layers 16, and protective liners 330 at block S424, and removing the protective liners 330 and interposer layer 16 from between the nanosheet channel layers 15, such as in a sheet release process, at block S426.

FIG. 40 is a partial view similar to FIG. 38, illustrating the structure of the device 100 after block S426 is performed. As shown, after the protective liners 330 and interposer layers 16 are removed, the nanosheet channel layers 15 remain. As further shown in FIG. 40, the inter-diffusion regions 390 remain on the nanosheet channel layers 15.

In FIG. 34, method further includes, at block S427, removing the inter-diffusion region 390. For example, an etch selective to the material of the inter-diffusion region 390 may be performed.

FIG. 41 is a partial view similar to FIG. 40, illustrating the structure of the device 100 after block S427 is performed. As shown, the nanosheet channel layer 15 is thinned in a central region, but substantially retains the original thickness at the inner spacer 340. As shown, the interface 345 between the inner spacer 340 and the nanosheet channel layer 15 has a length L2. In certain embodiments, length L2 is equal to length L1. In certain embodiments, length L2 is at least 99% of length L1, such as at least 95% of length L1, at least 90% of length L1, at least 85% of length L1, or at least 80% of length L1.

The embodiment of FIG. 34 may continue with forming metal gates in the gate cavities at block S428 and performing further processing at block S430, as described above.

FIGS. 42-45 illustrate an embodiment of method 400 in which the protective liner 330 is formed with a gradient of hardness. Specifically, as shown in FIG. 42, at terminal regions 336 the protective liner 330 is relatively hard, and in a central region 338 the protective liner 330 is relatively soft. The protective liner 330 may be formed from silicon oxide or another suitable material. In certain embodiments, the protective liner 330 is formed from flowable silicon oxide. The protective liner may be formed according to method 400 of FIG. 20 or FIG. 34.

FIG. 43 illustrates the structure after the formation of the inner spacers 340 and the source/drain features 350, such as after blocks S414 and S416 in method 400.

FIG. 44 illustrates the structure after performing the process to activate the source/drain features while preventing or reducing interdiffusion in the nanosheet layers 15, such as after blocks S450 and S460. As shown, the inter-diffusion region 390 is formed within a central region 398 aligned with the soft central region 338 of the protective liner 330. In terminal regions of the nanosheet channel layer 15 adjacent to the central region 398, no inter-diffusion region is formed.

FIG. 45 illustrates the structure after removing the inter-diffusion region 390, such as after block S427. As shown, only the central region 398 is thinned by the removal of the inter-diffusion region 390. Thus, the nanosheet channel layer 15 retains it thickness at the interface with the inner spacers 340.

FIGS. 46-49 illustrate an embodiment of method 400 in which the protective liner 330 is formed with an inner layer 331 and an outer layer 332.

As shown in FIG. 46, the inner layer 331 forms a continuous interface with the nanosheet layer 15, such that no part of the outer layer 332 is in contact with the nanosheet layer 15.

In the inner layer 331 may be formed as described above in relation to the liner 330 in the method of FIG. 34. Then, the outer layer 332 may be formed as described in relation to FIG. 42, i.e., with a softer central region 338 and hard terminal regions 336.

FIG. 47 illustrates the structure after the formation of the inner spacers 340 and the source/drain features 350, such as after blocks S414 and S416 in method 400. It is noted that the inner layer 331 may terminate at the inner spacers 340 as shown in the upper inner layer 331 in FIG. 47. Alternatively, the inner layer 331 may extend beyond the inner spacers 340 and separate the inner spacers 340 from the nanosheet layer 15 as shown in the lower inner layer 331 in FIG. 47. Further, it is noted that in a typical embodiment the upper and lower inner layers 331 will either both terminate at the inner spacers 340 or both extend beyond the inner spacers 340, and FIG. 47 merely illustrates an example of each type of inner spacer 340 in a single view.

FIG. 48 illustrates the structure after performing the process to activate the source/drain features while preventing or reducing interdiffusion in the nanosheet layers 15, such as after blocks S450 and S460. As shown, the inter-diffusion region 390 is formed within a central region 398 aligned with the soft central region 338 of the protective liner 330. In terminal regions of the nanosheet channel layer 15 adjacent to the central region 398, no inter-diffusion region is formed.

Due to the addition of the inner layer 331 to the outer layer 332 formed with a soft central region 338, the thickness of the inter-diffusion region 390 may be reduced as compared to the embodiment of FIG. 44.

FIG. 49 illustrates the structure after removing the inter-diffusion region 390, such as after block S427. As shown, only the central region 398 is thinned by the removal of the inter-diffusion region 390. Thus, the nanosheet channel layer 15 retains it thickness at the interface with the inner spacers 340.

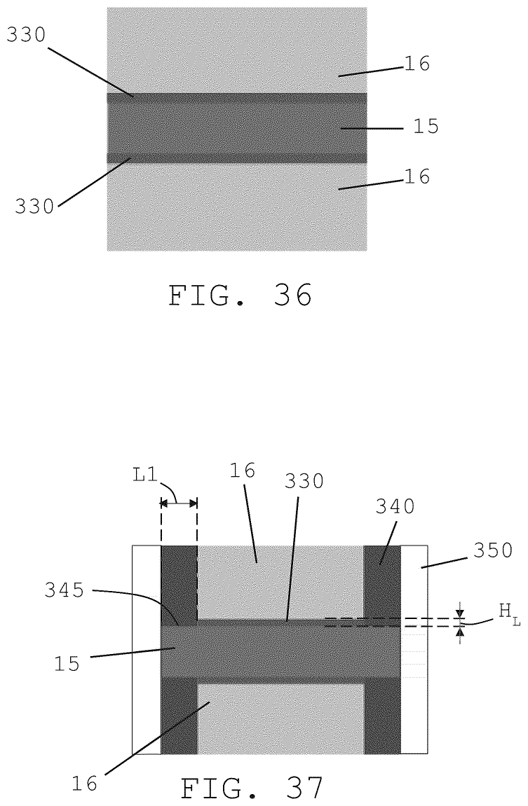

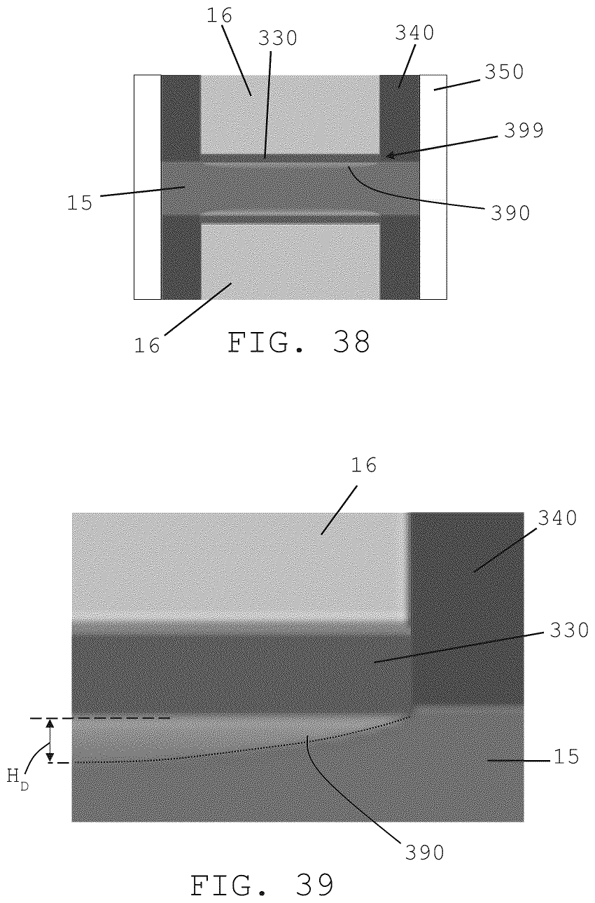

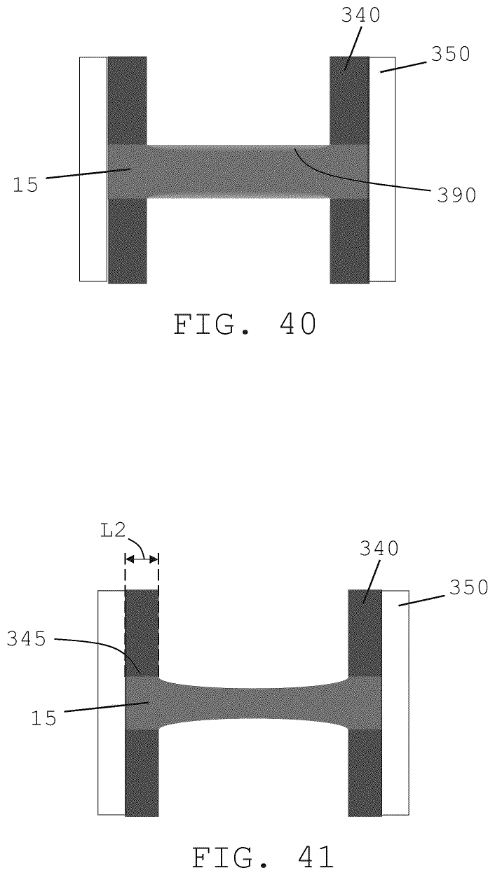

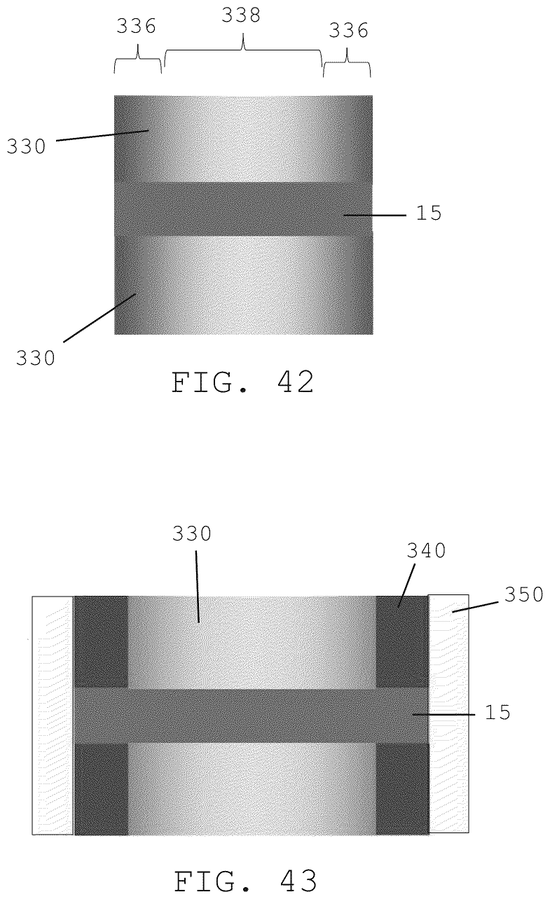

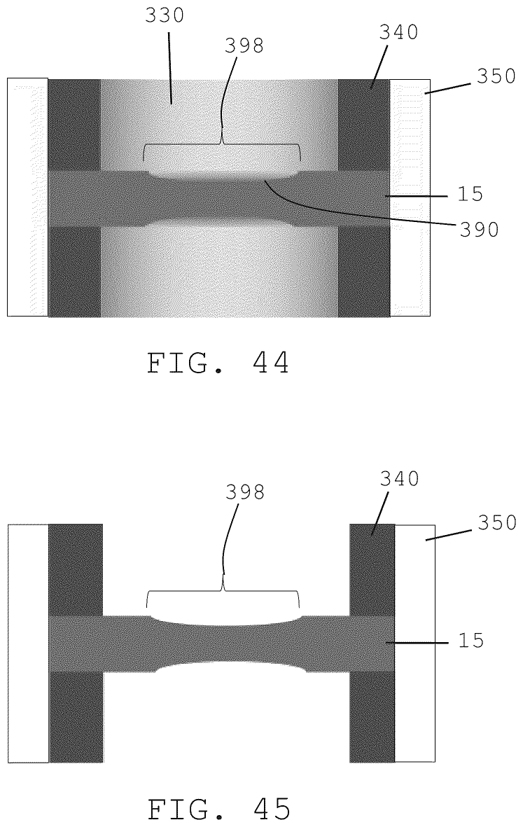

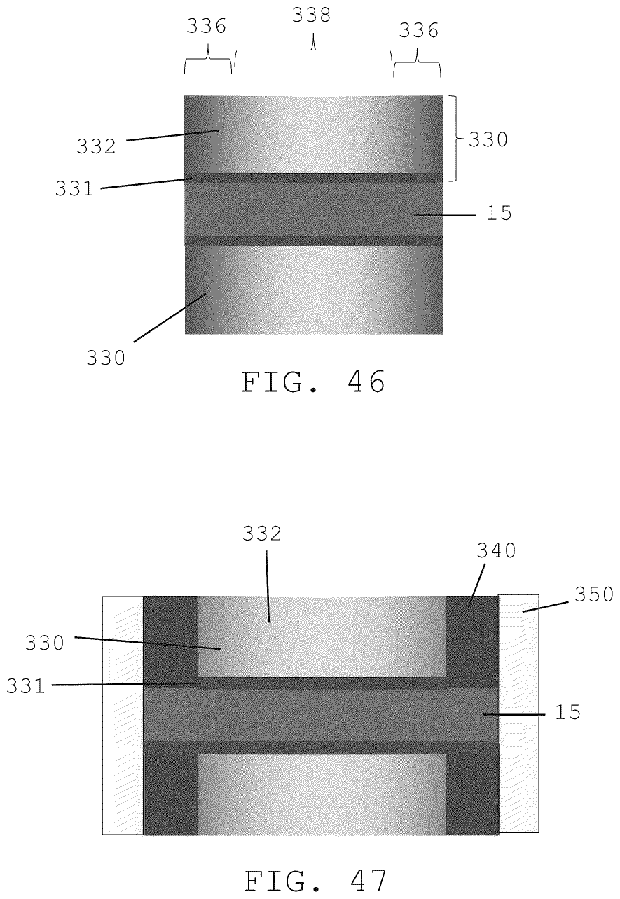

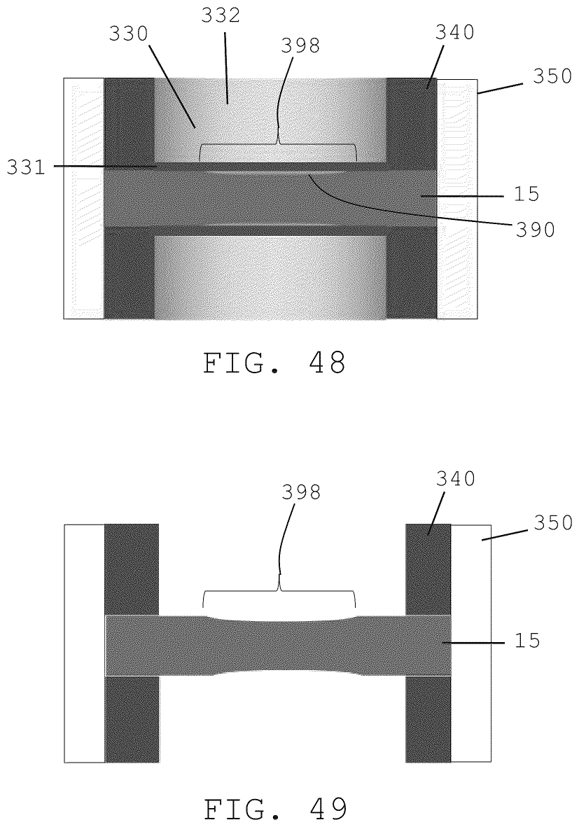

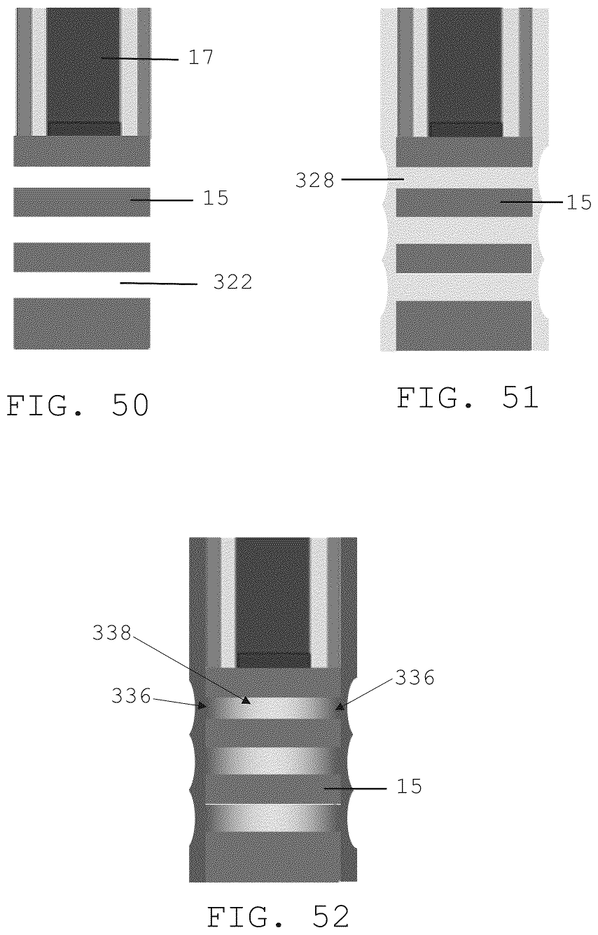

FIGS. 50-52 illustrate a process for forming a protective liner 330, or an outer layer 332 of a protective liner 330, such as in accordance with blocks S410 and S412. FIGS. 50-53 are Y-cut cross-sectional view of the nanosheet channel layers 15 under a sacrificial gate structure 17.

FIG. 50 illustrates the structure of a device 100 after removing the interposer layers 16, such as after block S408. As shown, voids 322 are formed between the nanosheet layers 15.

FIG. 51 illustrates the structure of the device 100 after depositing a protective liner material 328, such as after block S410. As shown, the protective liner material 328 fills the voids 322. In certain embodiments, the protective liner material 328 is flowable silicon oxide deposited in a refill process.

FIG. 52 illustrates the structure of the device 100 after forming a protective liner 330 from the protective liner material 328, such as after block S412. Specifically, in the embodiment of FIGS. 50-53, a process is performed to cure the protective liner material 328 or convert the protective liner material 328 to the protective liner 330 (or outer layer 332). In certain embodiments, an ultraviolet (UV) or forming gas, e.g., H₂ gas, curing process is performed. As a result, the terminal regions 336 are hardened while the central region 338 remains soft.

FIGS. 53-55 illustrate a process in which the interface between each inner spacer 340 and the respective interposer layer 16 and protective liner 330 is formed with a convex profile.

FIG. 53 illustrates the structure of the device after forming the inner spacers 340 at block S414 and forming the source/drain features 350 at block S416. As shown, an interface 345 is formed between the inner spacers 340 and the interposer layer 16 and protective liners 330. In the illustrated cross-section, the interface 345 is convex shaped. Specifically, the interface 345 extends from a terminal end 346 in contact with a liner 330, to an apex 348, to a terminal end 346 in contact with the liner 330. As shown, the apex 348 is located at a maximum distance D4 from the source/drain feature 350, and each terminal end 346 is located at a minimum distance D5 from the source/drain feature 350. As shown, distance D4 is greater than distance D5 by distance D6.

FIG. 54 illustrates the structure after performing the process to activate the source/drain features while preventing or reducing interdiffusion in the nanosheet layers 15, such as after blocks S450 and S460. As shown, the inter-diffusion region 390 is formed within a central region 398. In terminal regions of the nanosheet channel layer 15 adjacent to the central region 398, no inter-diffusion region is formed.

It has been found that the convex shape of the inner spacers 340 reduces inter-diffusion and minimizes the size of the inter-diffusion region 390, particularly in the terminal regions of the nanosheet channel layer 15.

FIG. 55 illustrates the structure after removing the inter-diffusion region 390, such as after block S427. As shown, only the central region 398 is thinned by the removal of the inter-diffusion region 390. Thus, the nanosheet channel layer 15 retains it thickness at the interface with the inner spacers 340.

In FIGS. 53-55, the protective liner 330 extends to and terminates at the inner spacers 340. However, the protective liner 330 may extend past the inner spacers 340 to the source/drain features 350.

For example, FIGS. 56-58 illustrate a process in which the interface between each inner spacer 340 and the respective interposer layer 16 and protective liner 330 is formed with a convex profile. In FIGS. 56-58, the protective liner 330 extends to contact with the source/drain features 350.

FIG. 56 illustrates the structure of the device after forming the inner spacers 340 at block S414 and forming the source/drain features 350 at block S416. As shown, an interface 345 is formed between the inner spacers 340 and the interposer layer 16 and protective liners 330. In the illustrated cross-section, the interface 345 is convex shaped. Specifically, the interface 345 extends from a terminal end 346 in contact with a liner 330, to an apex 348, to a terminal end 346 in contact with the liner 330. As shown, the apex 348 is located at a maximum distance D4 from the source/drain feature 350, and each terminal end 346 is located at a minimum distance D5 from the source/drain feature 350. As shown, distance D4 is greater than distance D5 by distance D6.

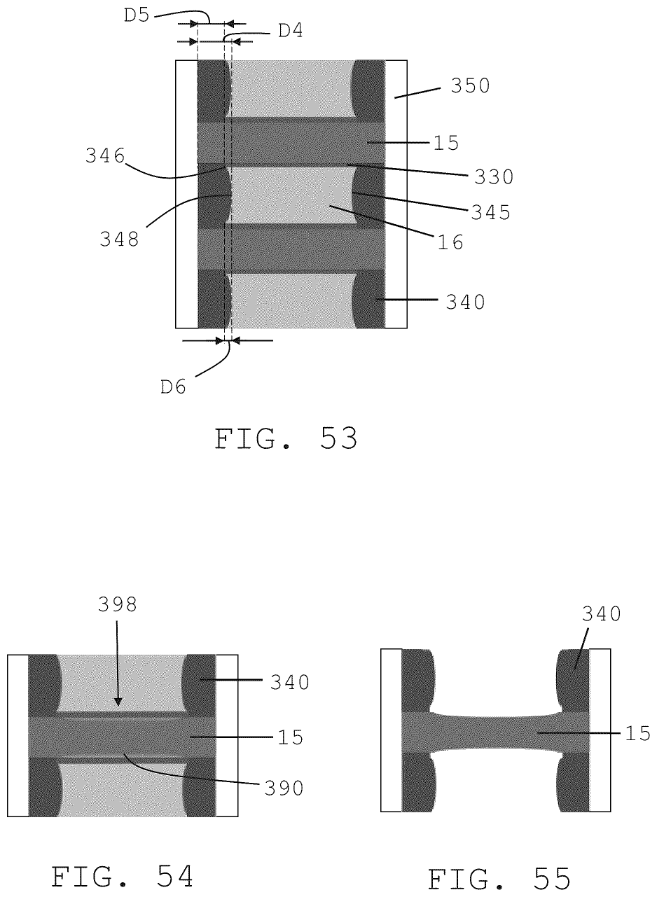

FIG. 57 illustrates the structure after performing the process to activate the source/drain features while preventing or reducing interdiffusion in the nanosheet layers 15, such as after blocks S450 and S460. As shown, the inter-diffusion region 390 is formed within a central region 398. In terminal regions of the nanosheet channel layer 15 adjacent to the central region 398, no inter-diffusion region is formed.

It has been found that the convex shape of the inner spacers 340 reduces inter-diffusion and minimizes the size of the inter-diffusion region 390, particularly in the terminal regions of the nanosheet channel layer 15.

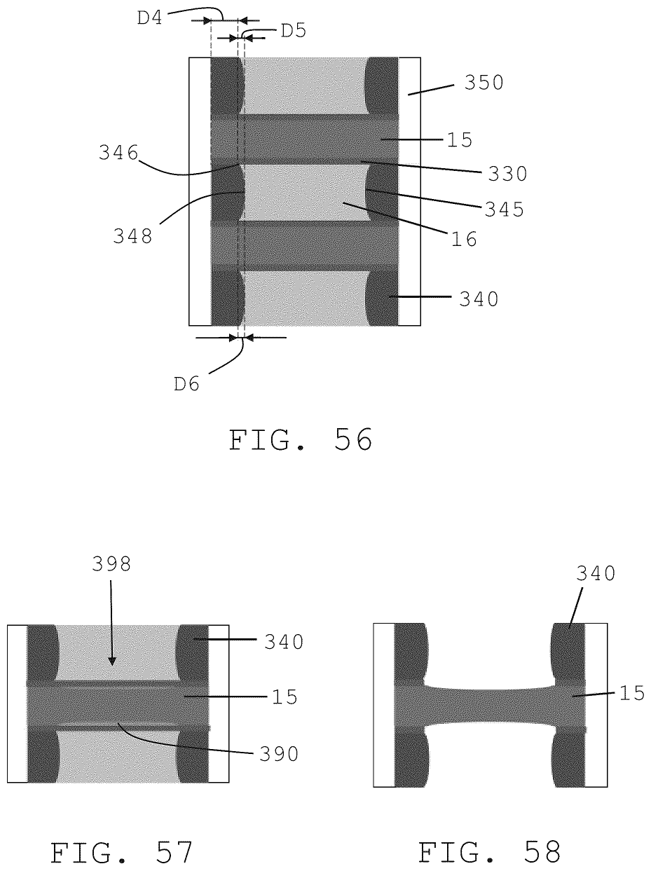

FIG. 58 illustrates the structure after removing the inter-diffusion region 390, such as after block S427. As shown, only the central region 398 is thinned by the removal of the inter-diffusion region 390. Thus, the nanosheet channel layer 15 retains it thickness at the interface with the inner spacers 340.

According to embodiments herein, a device 100 may be formed with a number of transistors, each having three nanosheet channel layers 500.

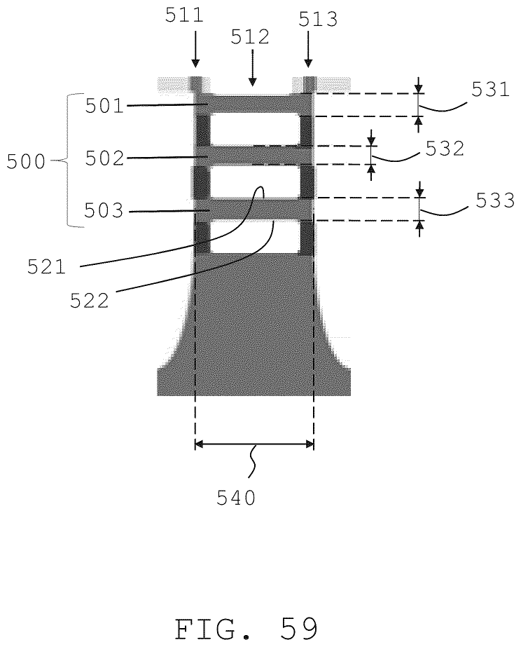

In FIG. 59, a single transistor of the device 100 is illustrated. Each transistor in the device includes a top nanosheet channel layer 501, a middle nanosheet channel layer 502, and a bottom nanosheet channel layer 503. Each nanosheet channel layer 500 has a left edge 511, a center 512, and a right edge 513.

In an exemplary embodiment, the nanosheet channel layers 500 are provided with consistent thicknesses across the device.

For example, top nanosheet channel layer 501 has a thickness 531 at left edge 511, at center 512, and at right edge 513.

In an exemplary device having a number of transistors, thickness 531 at the left edge 511 has a minimum value of 5.8 nm, a maximum value of 5.9 nm, and a mean value of 5.9 nm. In an exemplary device, thickness 531 at center 512 has a minimum value of 5.6 nm, a maximum value of 6.0 nm, and a mean value of 5.6 nm. In an exemplary device, thickness 531 at right edge 513 has a minimum value of 6.4 nm, a maximum value of 6.5 nm, and a mean value of 6.4 nm.

As shown, middle nanosheet channel layer 502 has a thickness 532 at left edge 511, at center 512, and at right edge 513.

In an exemplary device having a number of transistors, thickness 532 at left edge 511 has a minimum value of 6.2 nm, a maximum value of 6.2 nm, and a mean value of 6.2 nm. In an exemplary device, thickness 532 at center 512 has a minimum value of 6.2 nm, a maximum value of 6.5 nm, and a mean value of 6.3 nm. In an exemplary device, thickness 532 at right edge 513 has a minimum value of 6.4 nm, a maximum value of 6.5 nm, and a mean value of 6.5 nm.

As shown, bottom nanosheet channel layer 503 has a thickness 533 at left edge 511, at center 512, and at right edge 513.

In an exemplary device having a number of transistors, thickness 533 at left edge 511 has a minimum value of 6.2 nm, a maximum value of 6.3 nm, and a mean value of 6.2 nm. In an exemplary device, thickness 533 at center 512 has a minimum value of 6.2 nm, a maximum value of 6.9 nm, and a mean value of 6.6 nm. In an exemplary device, thickness 533 at right edge 513 has a minimum value of 6.5 nm, a maximum value of 6.7 nm, and a mean value of 6.6 nm.

Thus, for all nanosheet channel layers 500, the channel thickness variation is no more than 0.7 nm. In certain embodiments, the channel thickness variation for a nanosheet channel layer 500 is less than 0.7 nm, such as less than 0.6 nm, less than 0.5 nm, less than 0.4 nm, less than 0.3 nm, less than 0.2 nm, less than 0.1 nm, or less than 0.05 nm.

In certain embodiments, the channel thickness variation for a nanosheet channel layer 500 is less than 12.5% based on the minimum thickness of the nanosheet channel layer 500. For example, the channel thickness variation for a nanosheet channel layer 500 may be less than 12%, less than 11%, less than 10%, less than 9%, less than 8%, less than 7%, less than 6%, less than 5%, less than 4%, less than 3%, less than 2%, less than 1%, or less than 0.5%, all based on the minimum thickness of the nanosheet channel layer 500.

In an exemplary embodiment, the nanosheet channel layers 500 are provided with consistent lengths 540 across the device 100.

For example, top nanosheet channel layer 501 has a length 540 at upper surface 521. In an exemplary device, the length 540 of the top nanosheet channel layer 501 at upper surface 521 has a minimum value of 14.7 nm, a maximum value of 14.7 nm, and a mean value of 14.7 nm.

Further, top nanosheet channel layer 501 has a length 540 at lower surface 522. In an exemplary device, the length 540 of the top nanosheet channel layer 501 at lower surface 522 has a minimum value of 14.9 nm, a maximum value of 14.9 nm, and a mean value of 14.9 nm.

For top nanosheet channel layer 501, the variation between the length 540 at the upper surface and the length 540 at the lower surface is less than 0.2 nm.

Middle nanosheet channel layer 502 has a length 540 at upper surface 521. In an exemplary device, the length 540 of the middle nanosheet channel layer 502 at upper surface 521 has a minimum value of 15.7 nm, a maximum value of 16.4 nm, and a mean value of 16.0 nm.

Further, middle nanosheet channel layer 502 has a length 540 at lower surface 522. In an exemplary device, the length 540 of the middle nanosheet channel layer 502 at lower surface 522 has a minimum value of 16.0 nm, a maximum value of 17.4 nm, and a mean value of 16.7 nm.

For middle nanosheet channel layer 502, the variation between the length 540 at the upper surface and the length 540 at the lower surface is less than 0.7 nm.

Bottom nanosheet channel layer 503 has a length 540 at upper surface 521. In an exemplary device, the length 540 of the bottom nanosheet channel layer 503 at upper surface 521 has a minimum value of 17.3 nm, a maximum value of 18.6 nm, and a mean value of 17.9 nm.

Further, bottom nanosheet channel layer 503 has a length 540 at lower surface 522. In an exemplary device, the length 540 of the bottom nanosheet channel layer 503 at lower surface 522 has a minimum value of 18.2 nm, a maximum value of 18.4 nm, and a mean value of 18.3 nm.

For bottom nanosheet channel layer 501, the variation between the length 540 at the upper surface and the length 540 at the lower surface is less than 0.4 nm.

Thus, for all nanosheet channel layers 500, the channel length variation across the device is no more than 1.5 nm. In certain embodiments, the channel thickness variation for a nanosheet channel layer 500 is less than 1.5 nm, such as less than 1.4 nm, less than 1.3 nm, less than 1.2 nm, less than 1.1 nm, less than 1.0 nm, less than 0.9 nm, less than 0.8 nm, 0.7 nm, such as less than 0.6 nm, less than 0.5 nm, less than 0.4 nm, less than 0.3 nm, less than 0.2 nm, less than 0.1 nm, or less than 0.05 nm.

In certain embodiments, the channel length variation for a nanosheet channel layer 500 is less than 11% based on the minimum length of the nanosheet channel layer 500. For example, the channel length variation for a nanosheet channel layer 500 may be less than 10%, less than 9%, less than 8%, less than 7%, less than 6%, less than 5%, less than 4%, less than 3%, less than 2%, less than 1%, or less than 0.5%, all based on the minimum length of the nanosheet channel layer 500.

While various features are illustrated in relation to method 400 of FIGS. 20 and 34, it is noted that an embodiments may include any of the specific features in a combination, even if such combination is not specifically described herein.

In one embodiment, method includes forming nanosheet channel layers over a semiconductor material; forming a protective liner on each of the nanosheet channel layers; forming fin structures from the nanosheet channel layers and from a portion of the semiconductor material; forming a sacrificial gate over the semiconductor material; performing a thermal anneal process while the protective liners are located on the nanosheet channel layers; removing at least a portion of a selected fin structure and an overlying portion of the sacrificial gate located over the portion of the selected fin structure to form a trench; forming an insulation structure in the trench; removing a remaining portion of the sacrificial gate to form a gate cavity, wherein the gate cavity is partially defined by an end wall of the insulation structure; removing the protective liners from the nanosheet channel layers; and forming a metal gate in the cavity.

In certain embodiments, the method further includes forming STI features over the semiconductor substrate and adjacent to the first fin structure, wherein at a plane defined by an uppermost surface of the STI features, the thickness of the insulation structure is from 35 to 50 percent of the pitch size.

In certain embodiments, the method further includes forming interposer layers over the semiconductor material, wherein the interposer layers are interleaved with the nanosheet channel layers; and removing the interposer layers to form voids; wherein forming the protective liner on each of the nanosheet channel layers includes forming the protective liners in the voids.

In certain embodiments of the method, a selected protective liner contacts adjacent nanosheet channel layers.

In certain embodiments of the method, forming the protective liner on each of the nanosheet channel layers includes forming each protective liner with a relative soft central region and relative hard terminal regions.

In certain embodiments of the method, forming the protective liner on each of the nanosheet channel layers includes depositing a protective liner material and curing the protective liner material.

In certain embodiments, the method further includes forming interposer layers over a semiconductor material, wherein the interposer layers are interleaved with the protective liners and nanosheet channel layers, and wherein each interposer layer is separated from a respective nanochannel layer by a respective protective layer; and removing the interposer layers after performing the thermal anneal process.

In certain embodiments, the method further includes forming inner spacers laterally adjacent to each interposer layer, wherein each inner spacer has a convex profile.

In certain embodiments of the method, each nanosheet channel layer has a central region located between opposite terminal regions, and wherein the method further includes preventing formation of an inter-diffusion region in the terminal regions of the nanosheet channel layers.

In certain embodiments of the method, each nanosheet channel layer has a central region located between opposite terminal regions, wherein an inter-diffusion region forms in the central region of each nanosheet channel layer during the thermal anneal process, and wherein the method further includes removing the inter-diffusion regions.

In certain embodiments, the method further includes etching the nanosheet channel layers around the sacrificial gate to form source/drain region cavities; forming inner spacers between the nanosheet channel layers and the source/drain region cavities; and forming source/drain features in the source/drain region cavities, wherein the thermal anneal process activates the source/drain features.

In another embodiment, a method includes forming nanosheet channel layers over a semiconductor material; forming fin structures over the semiconductor material; forming a sacrificial gate structure over the nanosheet channel layers; etching the nanosheet channel layers around the sacrificial gate structure to form source/drain region cavities; forming source/drain features in the source/drain region cavities; while performing a thermal anneal process to activate the source/drain features, blocking inter-diffusion of the nanosheet channel layers with protective liners; replacing the sacrificial gate structure with a metal gate including a gate dielectric liner and a metal fill; removing at least a portion of the fin structure and an overlying portion of the metal gate located over the portion of the fin structure to form a trench; and forming an insulation structure in the trench, wherein the insulation structure has a first end wall and a second end wall defining a thickness therebetween; wherein a first fin structure has a first sidewall and a second sidewall; wherein a pitch size is defined from the first sidewall to the first end wall; and wherein the thickness of the insulation structure is from 35 to 70 percent of the pitch size.

In certain embodiments of the method, forming the insulation structure in the trench includes forming the insulation structure in direct contact with the metal fill of the metal gate.

In certain embodiments of the method, at a plane defined by an uppermost surface of the first fin structure, the thickness of the insulation structure is from 60 to 70 percent of the pitch size.

In certain embodiments of the method, the second sidewall of the first fin structure is distanced from the insulation structure by 20 nm to 45 nm.

In certain embodiments, the method further includes forming STI features adjacent to the first fin structure, wherein at a plane defined by an uppermost surface of the STI features, the thickness of the insulation structure is from 35 to 50 percent of the pitch size.

In another embodiment, a semiconductor device includes a semiconductor substrate formed with a first fin structure and a second fin structure; a first metal gate segment over the semiconductor substrate and the first fin structure; a second metal gate segment over the semiconductor substrate and the second fin structure, wherein the first metal gate segment and the second metal gate segment are co-linear and are separated from one another by a gap; and an insulation structure located in the gap and insulating the first metal gate segment from the second metal gate segment, wherein the insulation structure extends into the semiconductor substrate; wherein the insulation structure has a first end wall and a second end wall defining a thickness therebetween; wherein the first fin structure has a first sidewall and a second sidewall; wherein a pitch size is defined from the first sidewall to the first end wall; and wherein the thickness of the insulation structure is from 35 to 70 percent of the pitch size.

In certain embodiments of the semiconductor device, each metal gate segment includes a metal fill and a dielectric liner, and wherein the metal fill directly contacts the end walls of the insulation structure.

In certain embodiments of the semiconductor device, each metal gate segment includes a metal fill and a dielectric liner, and wherein the dielectric liner is located between the end walls of the insulation structure and the insulation structure.

In certain embodiments of the semiconductor device, at a plane defined by an uppermost surface of the fin structures, the thickness of the insulation structure is from 60 to 70 percent of the pitch size.

In another embodiment, a semiconductor device 100 includes a semiconductor substrate 10 formed with a first fin structure 12 and a second fin structure 12; a first metal gate segment 301 over the semiconductor substrate and the first fin structure; a second metal gate segment 302 over the semiconductor substrate and the second fin structure, wherein the first metal gate segment and the second metal gate segment are co-linear and are separated from one another by a gap 303; and an insulation structure 40 located in the gap and insulating the first metal gate segment from the second metal gate segment, wherein the dielectric structure extends into the semiconductor substrate; wherein the insulation structure has a first end wall 41 and a second end wall 42 defining a thickness Dc/Lc therebetween; wherein the first fin structure has a first sidewall 151 and a second sidewall 152; wherein a pitch size Da/La is defined from the first sidewall 151 to the first end wall 41; and wherein the thickness of the insulation structure is from 35 to 70 percent of the pitch size.

In certain embodiments of the semiconductor device, each metal gate segment includes a metal fill and a dielectric liner, and the metal fill directly contacts the end walls of the insulation structure.

In certain embodiments of the semiconductor device, each metal gate segment includes a metal fill and a dielectric liner, and the dielectric liner is located between the end walls of the insulation structure and the insulation structure.

In certain embodiments of the semiconductor device, at a plane 915 defined by an uppermost surface of the fin structures, the thickness of the insulation structure is from 60 to 70 percent of the pitch size.

In certain embodiments of the semiconductor device, the second sidewall of the first fin structure is distanced from the insulation structure by 20 nm to 45 nm.

In certain embodiments, the semiconductor device further includes STI features over the semiconductor substrate and adjacent to the fin structures, wherein at a plane 914 defined by an uppermost surface of the STI features, the thickness of the insulation structure is from 35 to 50 percent of the pitch size.

In certain embodiments, the semiconductor device further includes STI features over the semiconductor substrate and adjacent to the fin structures; and an STI hard mask 21 located over the STI features, wherein at a plane 921 defined by an uppermost surface of the STI hard mask, the thickness of the insulation structure is from 45 to 55 percent of the pitch size.

In certain embodiments, the semiconductor device further includes STI features over the semiconductor substrate and adjacent to the fin structures; and an STI hard mask 21 located over the STI features, wherein the STI hard mask separates each metal gate segment from the STI features.

In certain embodiments of the semiconductor device, the STI hard mask contacts the insulation structure and the first fin structure.

In another embodiment, a method includes forming fin structures 12 over a semiconductor material 10; forming a sacrificial layer 17 over the semiconductor material; removing at least a portion of the fin structure and an overlying portion of the sacrificial layer located over the portion of the fin structure to form a trench 50; forming an insulation structure 40 in the trench; removing a remaining portion of the sacrificial layer to form a cavity 70, wherein the cavity is partially defined by an end wall 41 of the insulation structure; and forming a metal gate 301 in the cavity.

In certain embodiments of the method, forming the metal gate in the cavity includes lining the cavity with a liner, wherein the liner is formed on the insulation structure; and filling the cavity with a fill material.

In certain embodiments of the method, the insulation structure has a first end wall 41 and a second end wall 42 defining a thickness Dc/Lc therebetween; the fin structure has a first sidewall 151 and a second sidewall 152; a pitch size Da/La is defined from the first sidewall 151 to the first end wall 41; and the thickness of the insulation structure is from 35 to 70 percent of the pitch size.

In certain embodiments of the method, at a plane 915 defined by an uppermost surface of the fin structure, the thickness of the insulation structure is from 60 to 70 percent of the pitch size.

In certain embodiments of the method, the second sidewall of the fin structure is distanced from the insulation structure by 20 nm to 45 nm.

In certain embodiments, the method further includes forming STI features over the semiconductor substrate and adjacent to the fin structure, wherein at a plane 914 defined by an uppermost surface of the STI features, the thickness of the insulation structure is from 35 to 50 percent of the pitch size.\

In certain embodiments, the method further includes forming STI features over the semiconductor substrate and adjacent to the fin structure; and forming an STI hard mask over the STI features, wherein the STI hard mask separates the metal gate from the STI features.

In another embodiment, a method includes forming fin structures 12 over a semiconductor material 10; forming a sacrificial gate 17 over the semiconductor material; replacing the sacrificial gate with a metal gate including a gate dielectric liner and a metal fill; removing at least a portion of the fin structure and an overlying portion of the metal gate located over the portion of the fin structure to form a trench 50; and forming an insulation structure 40 in the trench, wherein the insulation structure has a first end wall 41 and a second end wall 42 defining a thickness Dc/Lc therebetween; wherein a first fin structure has a first sidewall 151 and a second sidewall 152; wherein a pitch size Da/La is defined from the first sidewall 151 to the first end wall 41; and wherein the thickness of the insulation structure is from 35 to 70 percent of the pitch size.

In certain embodiments of the method, forming the insulation structure 40 in the trench includes forming the insulation structure in direct contact with the metal fill of the metal gate.

In certain embodiments of the method, at a plane 915 defined by an uppermost surface of the fin structure, the thickness of the insulation structure is from 60 to 70 percent of the pitch size.

In certain embodiments of the method, the second sidewall of the fin structure is distanced from the insulation structure by 20 nm to 45 nm.

In certain embodiments of the method, forming STI features over the semiconductor substrate and adjacent to the fin structure, wherein at a plane 914 defined by an uppermost surface of the STI features, the thickness of the insulation structure is from 35 to 50 percent of the pitch size.

In an embodiment, a method includes forming nanosheet channel layers over a semiconductor material; forming a protective liner on each of the nanosheet channel layers; performing a thermal anneal process while the protective liners are located on the nanosheet channel layers; and removing the protective liners from the nanosheet channel layers.

In certain embodiments of the method, a selected protective liner contacts adjacent nanosheet channel layers.

In certain embodiments of the method, forming the protective liner on each of the nanosheet channel layers includes forming each protective liner with a relative soft central region and relative hard terminal regions.

In certain embodiments of the method, forming the protective liner on each of the nanosheet channel layers includes depositing a protective liner material and curing the protective liner material.

In certain embodiments, the method further includes forming interposer layers over a semiconductor material, wherein the interposer layers are interleaved with the protective liners and nanosheet channel layers, and wherein each interposer layer is separated from a respective nanochannel layer by a respective protective layer; and removing the interposer layers after performing the thermal anneal process.

In certain embodiments, the method further includes forming inner spacers laterally adjacent to each interposer layer, wherein each inner spacer has a convex profile.

In certain embodiments of the method, each nanosheet channel layer has a central region located between opposite terminal regions, and the method further includes preventing formation of an inter-diffusion region in the terminal regions of the nanosheet channel layers.

In certain embodiments of the method, each nanosheet channel layer has a central region located between opposite terminal regions, wherein an inter-diffusion region forms in the central region of each nanosheet channel layer during the thermal anneal process, and the method further includes removing the inter-diffusion regions.

In certain embodiments, the method further includes forming a sacrificial gate structure over the nanosheet channel layers; etching the nanosheet channel layers around the sacrificial gate structure to form source/drain region cavities; forming inner spacers between the nanosheet channel layers and the source/drain region cavities; forming source/drain features in the source/drain region cavities, wherein the thermal anneal process activates the source/drain features; removing the sacrificial gate structure to form a gate cavity; and after removing the protective liners from the nanosheet channel layers, forming a metal gate around the nanosheet channel layers.

In another embodiment, a method includes forming nanosheet channel layers over a semiconductor material; forming a sacrificial gate structure over the nanosheet channel layers; etching the nanosheet channel layers around the sacrificial gate structure to form source/drain region cavities; forming source/drain features in the source/drain region cavities; and, while performing a thermal anneal process to activate the source/drain features, blocking inter-diffusion of the nanosheet channel layers with protective liners.

In certain embodiments, the method further includes removing the sacrificial gate structure to form a gate cavity; removing the protective liners; and forming a metal gate around the nanosheet channel layers.

In certain embodiments, the method further includes forming the protective liners interleaved with the nanosheet channel layers before forming the sacrificial gate structure.

In certain embodiments, the method further includes forming the protective liners and interposer layers interleaved with the nanosheet channel layers before forming the sacrificial gate structure.

In certain embodiments, the method further includes forming interposer layers interleaved with the nanosheet channel layers before forming the sacrificial gate structure; removing the interposer layers after forming the source/drain region cavities to define voids; and forming the protective liners in the voids.

In certain embodiments, the method further includes forming inner portions of the protective liners and interposer layers interleaved with the nanosheet channel layers before forming the sacrificial gate structure; removing the interposer layers after forming the source/drain region cavities to define voids; and forming outer portions of the protective liners in the voids.

In certain embodiments of the method, forming the outer portions of the protective liners includes forming each outer portion with a relatively soft central region and relatively hard terminal regions.

In another embodiments, an intermediate structure of a gate all-around (GAA) transistor device includes a nanosheet channel layer having a central region between terminal regions; a protective liner contacting the nanosheet channel layer; and an inter-diffusion region located in the central region, wherein the inter-diffusion region does not extend into the terminal regions.

In certain embodiments, the intermediate structure of the GAA transistor device further includes an interposer layer, wherein the protective liner contacts the interposer layer, and wherein the protective liner is located between the nanosheet channel layer and the interposer layer.

In certain embodiments, the intermediate structure of the GAA transistor device further includes a sacrificial gate structure located over the nanosheet channel layer; and source/drain features, wherein the nanosheet channel layer, protective liner, and interposer layer are located between the source/drain features.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming nanosheet channel layers over a semiconductor material;
forming a protective liner on each of the nanosheet channel layers;
forming fin structures from the nanosheet channel layers and from a portion of the semiconductor material;
forming a sacrificial gate over the semiconductor material;
performing a thermal anneal process while the protective liners are located on the nanosheet channel layers;
removing at least a portion of a selected fin structure and an overlying portion of the sacrificial gate located over the portion of the selected fin structure to form a trench;
forming an insulation structure in the trench;
removing a remaining portion of the sacrificial gate to form a gate cavity, wherein the gate cavity is partially defined by an end wall of the insulation structure;
removing the protective liners from the nanosheet channel layers; and
forming a metal gate in the cavity.

2. The method of claim 1, further comprising:
forming STI features over the semiconductor substrate and adjacent to the first fin structure, wherein at a plane defined by an uppermost surface of the STI features, the thickness of the insulation structure is from 35 to 50 percent of the pitch size.

3. The method of claim 1, wherein the method further comprises:
forming interposer layers over the semiconductor material, wherein the interposer layers are interleaved with the nanosheet channel layers; and
removing the interposer layers to form voids;
wherein forming the protective liner on each of the nanosheet channel layers comprises forming the protective liners in the voids.

4. The method of claim 3, wherein a selected protective liner contacts adjacent nanosheet channel layers.

5. The method of claim 3, wherein forming the protective liner on each of the nanosheet channel layers comprises forming each protective liner with a relative soft central region and relative hard terminal regions.

6. The method of claim 3, wherein forming the protective liner on each of the nanosheet channel layers comprises depositing a protective liner material and curing the protective liner material.

7. The method of claim 1, further comprising:
forming interposer layers over a semiconductor material, wherein the interposer layers are interleaved with the protective liners and nanosheet channel layers, and wherein each interposer layer is separated from a respective nanochannel layer by a respective protective layer; and
removing the interposer layers after performing the thermal anneal process.

8. The method of claim 7, further comprising forming inner spacers laterally adjacent to each interposer layer, wherein each inner spacer has a convex profile.

9. The method of claim 1, wherein each nanosheet channel layer has a central region located between opposite terminal regions, and wherein the method further comprises preventing formation of an inter-diffusion region in the terminal regions of the nanosheet channel layers.

10. The method of claim 1, wherein each nanosheet channel layer has a central region located between opposite terminal regions, wherein an inter-diffusion region forms in the central region of each nanosheet channel layer during the thermal anneal process, and wherein the method further comprises removing the inter-diffusion regions.

11. The method of claim 1, further comprising:
etching the nanosheet channel layers around the sacrificial gate to form source/drain region cavities;
forming inner spacers between the nanosheet channel layers and the source/drain region cavities; and
forming source/drain features in the source/drain region cavities, wherein the thermal anneal process activates the source/drain features.

12. A method comprising:
forming nanosheet channel layers over a semiconductor material;
forming fin structures over the semiconductor material;
forming a sacrificial gate structure over the nanosheet channel layers;
etching the nanosheet channel layers around the sacrificial gate structure to form source/drain region cavities;
forming source/drain features in the source/drain region cavities;
while performing a thermal anneal process to activate the source/drain features, blocking inter-diffusion of the nanosheet channel layers with protective liners;
replacing the sacrificial gate structure with a metal gate including a gate dielectric liner and a metal fill;
removing at least a portion of the fin structure and an overlying portion of the metal gate located over the portion of the fin structure to form a trench; and
forming an insulation structure in the trench, wherein
wherein the insulation structure has a first end wall and a second end wall defining a thickness therebetween;
wherein a first fin structure has a first sidewall and a second sidewall;
wherein a pitch size is defined from the first sidewall to the first end wall; and
wherein the thickness of the insulation structure is from 35 to 70 percent of the pitch size.

13. The method of claim 12, wherein forming the insulation structure in the trench comprises forming the insulation structure in direct contact with the metal fill of the metal gate.

14. The method of claim 12, wherein at a plane defined by an uppermost surface of the first fin structure, the thickness of the insulation structure is from 60 to 70 percent of the pitch size.

15. The method of claim 12, wherein the second sidewall of the first fin structure is distanced from the insulation structure by 20 nm to 45 nm.

16. The method of claim 12, forming STI features adjacent to the first fin structure, wherein at a plane defined by an uppermost surface of the STI features, the thickness of the insulation structure is from 35 to 50 percent of the pitch size.

17. A semiconductor device comprising:
a semiconductor substrate formed with a first fin structure and a second fin structure;
a first metal gate segment over the semiconductor substrate and the first fin structure;
a second metal gate segment over the semiconductor substrate and the second fin structure, wherein the first metal gate segment and the second metal gate segment are co-linear and are separated from one another by a gap; and
an insulation structure located in the gap and insulating the first metal gate segment from the second metal gate segment, wherein the insulation structure extends into the semiconductor substrate;
wherein the insulation structure has a first end wall and a second end wall defining a thickness therebetween;
wherein the first fin structure has a first sidewall and a second sidewall;
wherein a pitch size is defined from the first sidewall to the first end wall; and
wherein the thickness of the insulation structure is from 35 to 70 percent of the pitch size.

18. The semiconductor device of claim 17, wherein each metal gate segment comprises a metal fill and a dielectric liner, and wherein the metal fill directly contacts the end walls of the insulation structure.

19. The semiconductor device of claim 17, wherein each metal gate segment comprises a metal fill and a dielectric liner, and wherein the dielectric liner is located between the end walls of the insulation structure and the insulation structure.

20. The semiconductor device of claim 17, wherein at a plane defined by an uppermost surface of the fin structures, the thickness of the insulation structure is from 60 to 70 percent of the pitch size.
